(19) United States
(12) Patent Application Publication
(10) Pub. No.: US 2008/0206670 A1
(43) Pub. Date: Aug. 28, 2008

(54) INFRARED LASER-SENSITIVE PLANOGRAPHIC PRINTING PLATE PRECURSOR

(75) Inventors: Yuichi Shiraishi, Haibara-gun (JP); Koji Wariishi, Haibara-gun (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM CORPORATION, Tokyo (JP)

(21) Appl. No.: 12/037,257

(22) Filed: Feb. 26, 2008

(30) Foreign Application Priority Data
Feb. 27, 2007 (JP) 2007-047721

(51) Int. Cl. G03F 7/004

(52) U.S. Cl. 430/270.1

(57) ABSTRACT

The invention provides an infrared laser-sensitive planographic printing plate precursor, comprising: a support having a hydrophilic surface; and a single layer or a plurality of photosensitive layers disposed on the support having a hydrophilic surface, wherein the outermost layer of the photosensitive layers includes an infrared absorbent and a copolymer that includes, as copolymerization components, (i) an acrylate or methacrylate having an alkyl group having four or more carbon atoms, (ii) an acrylate or methacrylate having an alkyl group having 1 through 3 carbon atoms, and (iii) a polymerizing monomer having an acid group, and the amount of the acrylate or methacrylate having an alkyl group having four or more carbon atoms being in a range of 0.1 to 20 mole percent of the copolymer.

### CROSS-REFERENCE TO RELATED APPLICATION

This application claims priority under 35 USC 119 from Japanese Patent Application No. 2007-47721, the disclosure of which is incorporated by reference herein.

### BACKGROUND OF THE INVENTION

1. Field of the Invention

The present invention relates to an infrared laser-sensitive planographic printing plate precursor, and more specifically, to a direct infrared laser-sensitive planographic printing plate precursor that can realize direct plate making by scanning infrared laser light based on a digital signal from a computer or the like.

2. Description of the Related Art

In recent years, progress in laser technology has been remarkable, particularly in higher-output and smaller-size solid state and semiconductor lasers having an emission wavelength in a range from the near-infrared to infrared regions. Accordingly, when plate making is performed directly from digital data from a computer or the like, these lasers are extremely useful as an exposure-light source.

Infrared laser-sensitive planographic printing plate precursors that use an infrared laser that has an emission region in an infrared region as an exposure light source are planographic printing plate precursors that include, as essential components, a binder resin and an IR dye that absorbs light to generate heat. When an infrared laser is used to expose the infrared laser-sensitive planographic printing plate precursor, when the precursor has a positive-working photosensitive layer, in unexposed portions (image portions), the IR dye in the infrared laser-sensitive planographic printing plate precursor interacts with the binder to act as a dissolution inhibitor that substantially lowers the solubility of the binder resin. On the other hand, in exposed portions (non-image portions), the IR dye absorbs light to generate heat; as the result, the interaction is weakened between the IR dye and the binder resin. Accordingly, during development, the exposed portion (non-image portion) is dissolved in an alkali developing solution to form a planographic printing plate.

Such infrared laser-sensitive planographic printing plate precursors still have various problems. How to improve the lipophilicity of the surface thereof can be cited as one such problem. When the lipophilicity of the surface is low, problems may occur such as poor ink adhesion at the start of printing or the ink becoming incapable of adhering during printing. However, as the lipophilicity is improved, the hydrophobicity becomes stronger, so lowering the permeability to the developing solution; as the result, the developability tends to decrease. Accordingly, in order to combine the inking properties and the developability, a material that can balances the lipophilicity and the hydrophilicity is preferably used.

There have been various studies in order to overcome such problems. For instance, the use of a resin obtained by condensing an alkyl phenol having 3 to 15 carbon atoms and formaldehyde is proposed (see JP-A No. 50-125806). In this case, although the inking properties can be improved, the the developability is insufficient. Furthermore, when a printing plate material that uses such resin is used a lot, sludge is generated; accordingly, there is a problem in that the printing plate material can be used only in limited applications.

Furthermore, the use of a polymer that has a fluorine-based functional group is proposed (see JP-A No. 2002-72474). A compound that has a functional group containing many fluorine atoms has not only water repellency but also oil repellency; accordingly, when it is used a lot, there is a fear that not only the developability will be lowered but also the inking properties may be adversely affected. As the result, compounds that have a functional group containing many fluorine atoms can be used only to a limited extent; accordingly, inking properties can be improved only in a limited range.

### SUMMARY OF THE PRESENT INVENTION

The present invention has been made in view of the above circumstances and provides an infrared laser-sensitive planographic printing plate precursor.

A first aspect of the invention provides an infrared laser-sensitive planographic printing plate precursor, comprising: a support having a hydrophilic surface; and a single layer or a plurality of photosensitive layers disposed on the support having a hydrophilic surface, wherein the outermost layer of the photosensitive layer(s) comprises an infrared absorbent and a copolymer that includes, as copolymerization components, (i) an acrylate or methacrylate having an alkyl group having four or more carbon atoms, (ii) an acrylate or methacrylate having an alkyl group having 1 to 3 carbon atoms, and (iii) a polymerizing monomer having an acid group, and the amount of the acrylate or methacrylate having an alkyl group having four or more carbon atoms is in a range of 0.1 to 20 mole percent of the copolymer.

### DETAILED DESCRIPTION OF THE INVENTION

The invention intends to provide an infrared laser-sensitive planographic printing plate precursor that is excellent not only in the inking property of an image portion to enable to obtain excellent printed matters but also excellent as well in the developability and, even when many printing plates are continuously processed, can inhibit residue or sludge from generating in a developing solution.

The present inventors studied hard to overcome the problems and found that the problems could be overcome by an infrared laser-sensitive planographic printing plate precursor described below.

That is, the invention is an infrared laser-sensitive planographic printing plate precursor, comprising: a support having a hydrophilic surface; and a single layer or a plurality of photosensitive layers disposed on the support having a hydrophilic surface, wherein the outermost surface layer of the photosensitive layers comprises an infrared absorbent and a copolymer that includes, as copolymerization components, (i) an acrylate or methacrylate having an alkyl group having four or more carbon atoms, (ii) an acrylate or methacrylate having an alkyl group having 1 to 3 carbon atoms, and (iii) a polymerizing monomer having an acid group, and the amount of the acrylate or methacrylate having an alkyl group having four or more carbon atoms is in a range of 0.1 to 20 mole percent of the copolymer.

An infrared laser-sensitive planographic printing plate precursor of the invention (hereinafter, in some cases, referred to as a “planographic printing plate precursor of the invention”) is an infrared laser-sensitive planographic printing plate precursor, comprising: a support having a hydrophilic surface; a single layer or a plurality of photosensitive layers on the support having a hydrophilic surface, wherein the outermost surface layer of the photosensitive layers comprisesi an infrared absorbent and a copolymer that includes, as copolymerization components, (i) an acrylate or methacrylate having an alkyl group having four or more carbon atoms, (ii) an acrylate or methacrylate having an alkyl group having 1 to 3 carbon atoms, and (iii) a polymerizing monomer having an acid group, and the amount of the acrylate or methacrylate having an alkyl group having four or more carbon atoms being 0.1 to 20 mole percen of the copolymer (in some cases, such a copolymer is referred to as a “copolymer involving the invention”).

A planographic printing plate precursor of the invention, when it contains the copolymer involving the invention, becomes excellent in the inking property and the developability of an image portion and, even when many planographic printing plate precursors are continuously processed, can inhibit the residue or the sludge from generating in a developing solution. The reason for this is considered as described below. That is, since (meth)acrylate having an alkyl group having four or more carbon atoms has strong lipophilicity, owing to an action thereof, the inking property of an image portion can be imparted. Furthermore, when the amount of a copolymer component having strong lipophilicity is set in a range of 0.1 to 20 mole percent of the copolymer and (meth)acrylate having an alkyl group having 1 to 3 carbon atoms is contained as a copolymer component, the hydrophilicity can be inhibited from deteriorating and the developability can be maintained excellent. Still furthermore, it is considered that, owing to a polymerizing monomer having an acid group, the solubility and decomposing property to an alkaline developing solution is improved and thereby the residue and sludge can be inhibited from generating.

In the description, (meth)acrylate means acrylate or methacrylate.

The respective items will be described sequentially.

### [Copolymer Involving the Invention]

A copolymer involving the invention, which the outermost surface layer of the photosensitive layer contains is a copolymer that contains two or more kinds of (meth)acrylates having an alkyl group and a polymerizing monomer having an acid group as copolymerizing components.

Furthermore, in a copolymer involving the invention, at least one kind of at least two kinds of (meth)acrylates having an alkyl group is a (meth)acrylate having an alkyl group having at least four carbon atoms, and a (meth)acrylate having 1 to 3 carbon atoms is used in combination therewith. The alkyl group may be a branched one or one that has a ring structure.

### (i) (Meth)acrylate Having Alkyl Group Having Four or More Carbon Atoms

The alkyl group in a (meth)acrylate having an alkyl group having four or more carbon atoms has, from the viewpoints of obtaining sufficient hydrophilicity and the miscibility with other components, preferably 4 to 20 carbon atoms and more preferably 4 to 10 carbon atoms.

Examples of (meth)acrylates having an alkyl group having four or more carbon atoms include n-butyl acrylate, n-butyl methacrylate, i-butyl acrylate, i-butyl methacrylate, t-butyl acrylate, t-butyl methacrylate, n-pentyl acrylate, n-pentyl methacrylate, n-hexyl acrylate, n-hexyl methacrylate, 2-cyclohexylethyl acrylate, 2-cyclohexylethyl methacrylate, octyl acrylate, octyl methacrylate, dodecyl acrylate, dodecyl methacrylate, octadecyl acrylate and octadecyl methacrylate. Among these, n-butyl acrylate, n-butyl methacrylate, i-butyl acrylate, i-butyl methacrylate, t-butyl acrylate and t-butyl methacrylate are preferred.

The amount of the (meth)acrylate having an alkyl group having four or more carbon atoms is essentially set in a range of 0.1 to 20 mole percent of an entirety of constituents of the copolymer. When the amount of the (meth)acrylate having an alkyl group having four or more carbon atoms is less than 0.1 mole percent of the copolymer, an advantage of imparting the inking property to an image portion becomes smaller, and when it exceeds 20 mole percent, the hydrophilicity is largely deteriorated to lower the developability or the solubility. The amount of the (meth)acrylate having an alkyl group having four or more carbon atoms is preferably in a range of 1 to 20 mole percent and more preferably in a range of 5 to 18 mole percent of the copolymer.

### (ii) (Meth)acrylate Having Alkyl Group Having 1 to 3 Carbon Atoms

Examples of (meth)acrylates having an alkyl group having 1 to 3 carbon atoms include methyl acrylate, methyl methacrylate, ethyl acrylate, ethyl methacrylate, n-propyl acrylate, n-propyl methacrylate, i-propyl acrylate and i-propyl methacrylate. Among these, methyl methacrylate and ethyl methacrylate are preferred.

The (meth)acrylates having an alkyl group having 1 to 3 carbon atoms impart the hydrophilicity to a photosensitive layer. The amount of the (meth)acrylate having an alkyl group having 1 to 3 carbon atoms is preferably in a range of 25 to 90 mole percent to the copolymer and more preferably in a range of 30 to 85 mole percent of an entirety of constituents of the copolymer . When the amount of the (meth)acrylate having an alkyl group having 1 to 3 carbon atoms is set in a range of 25 to 90 mole percent, advantages of other copolymer components can be exerted at the maximum.

(iii) Polymerizing Monomer Having Acid Group

Examples of the acid groups in polymerizing monomers having an acid group include acidic groups cited in (1) to (6) below.
(1) Phenol group (—Ar—OH),
(2) sulfoneamide group (—SO₂NH—R),
(3) substituted sulfoneamide base acid group (hereinafter, referred to as “active imide group”) [—SO₂NHCOR, —SO₂NHSO₂R, —CONHSO₂R],
(4) carboxylic acid group (—CO₂H),
(5) sulfonic acid group (—SO₃H) and
(6) phosphoric acid group (—OPO₃H₂).

In the (1) through (6), Ar represents a divalent aryl linking group that may have a substituent and R represents a hydrocarbon group that may have a substituent.

Examples of the polymerizing monomers having an acidic group selected from the (1) to (6) include ones cited below.
(1) Examples of polymerizing monomers having a phenol group include acrylamide, methacrylamide, acrylic acid ester, methacrylic acid ester and hydroxy styrene, which contain a phenol group.
(2) As polymerizing monomers having a sulfoneamide group, low molecular weight compounds that have an acryloyl group, an allyl group or a vinyloxy group and a substituted or mono-substituted aminosulfonyl group or a substituted sulfonylimino group in a molecule are preferred, and examples thereof include compounds represented by formulas (i) to (v) below.

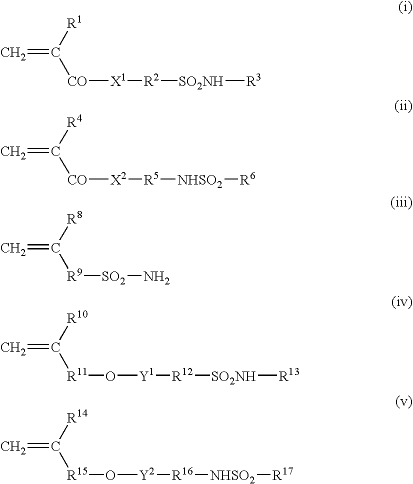

[In formulas (i) to (v), X¹ and X² each independently represent —O— or —NR⁷. R¹ and R⁴, each independently represent a hydrogen atom or —CH₃, R², R⁵, R⁹, R¹² and R¹⁶ each independently represent an alkylene group that may have a substituent group and has 1 to 12 carbon atoms, a cycloalkylene group, an arylene group or an aralkylene group. R³, R⁷ and R¹³ each independently represent a hydrogen atom, an alkyl group that may have a substituent group and has 1 to 12 carbon atoms, a cycloalkyl group, an aryl group or an aralkyl group. Furthermore, R⁶ and R¹⁷ each independently represent an alkyl group that may have a substituent group and has 1 to 12 carbon atoms, a cycloalkyl group, an aryl group or an aralkyl group. R⁸, R¹⁰ and R¹⁴ each independently represent a hydrogen atom or —CH₃. R¹¹ and R¹⁵ each independently represent an alkylene group that may have a single bond or a substituent group and has 1 to 12 carbon atoms, a cycloalkylene group, an arylene group or an aralkylene group. Y¹ and Y² each independently represent a single bond or CO.]
(3) As the polymerizing monomer having an active imide group, compounds that have an active imide group represented by a structural formula below and a polymerizable unsaturated group, respectively, at least one in a molecule can be cited.

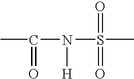

Specifically, N-(p-toluenesulfonyl)methacrylamide and N-(p-toluenesulfonyl)acrylamide can be preferably used.
(4) As the polymerizing monomer having a carboxylic acid group, acrylic acid, methacrylic acid, maleic acid and itaconic acid can be preferably used.
(5) As the polymerizing polymer having a sulfonic acid group, acrylamide, methacrylamide, acrylic acid ester and methacrylic acid ester, which have an alkylsulfonic acid group can be cited.
(6) As the polymerizing monomer having a phosphoric acid group, acrylamide, methacrylamide, acrylic acid ester and methacrylic acid ester, which have an alkylphosphoric acid group can be cited.

Among the polymerizing monomers having an acidic group selected from the (1) to (6), polymerizing monomers having (1) a phenol group, (4) a carboxylic acid group and (5) a sulfonic acid group are preferred and, in particular, polymerizing monomers having (1) a phenol group or (4) a carboxylic acid group are preferred.

Furthermore, the polymerizing monomers having an acidic group selected from the (1) to (6) is not limited particularly to one kind. Ones obtained by copolymerizing at least two kinds of polymerizing monomers each having the same acidic group or at least two kinds of polymerizing monomers each having an acidic group different from each other may be used.

The amount of the polymerizing monomer having the acidic group is, in view of obtaining sufficient solubility to an alkaline developing solution that does not substantially contain a solvent, preferably 3 mole percent or more of the copolymer and more preferably 5 mole percent or more of an entirety of constituents of the copolymer. Furthermore, in view of not damaging the lipophilicity of the (meth)acrylate having an alkyl group having four or more carbon atoms, the ratio is preferably 60 mole percent or less to the copolymer.

In the invention, as an example of compositions of preferably used copolymers involving the invention, examples of composition: (A) to (Q) are shown below. Described numerical values represent mole percent.
(A) n-butyl methacrylate/methyl acrylate/methacrylic acid=20/60/20,
(B) n-butyl methacrylate/ethyl methacrylate/methacrylic acid=15/70/15,
(C) n-butyl methacrylate/propyl methacrylate/methacrylic acid=10/55/35,
(D) i-butyl methacrylate/methyl methacrylate/methacrylic acid=15/60/25,
(E) i-butyl methacrylate/ethyl methacrylate/methacrylic acid=15/55/30,
(F) t-butyl methacrylate/methyl methacrylate/methacrylic acid=5/60/35,
(G) t-butyl methacrylate/ethyl methacrylate/methacrylic acid=5/50/45,
(H) n-hexyl methacrylate/ethyl methacrylate/methacrylic acid=15/50/35,
(I) 2-cyclohexylethyl methacrylate/ethyl methacrylate/methacrylic acid=5/65/30,
(J) octyl methacrylate/methyl methacrylate/methacrylic acid=5/70/25,
(K) dodecyl methacrylate/methyl methacrylate/methacrylic acid=1/65/34,
(L) octadecyl methacrylate/methyl methacrylate/methacrylic acid=3/60/37,
(M) n-butyl methacrylate/methyl methacrylate/ethyl methacrylate/methacrylic acid=10/40/30/20,
(N) n-butyl methacrylate/i-butyl methacrylate/methyl methacrylate/methacrylic acid=5/10/60/25,
(O) n-butyl methacrylate/ethyl methacrylate/itaconic acid=10/70/20,
(P) i-butyl methacrylate/methyl methacrylate/2-(p-hydroxyphenyl)ethyl methacryle=10/50/40, and
(Q) n-butyl methacrylate/methyl methacrylate/methacrylic acid/2-(p-hydroxyphenyl)ethyl methacrylate=15/60/20/5.

The weight average molecular weight of the copolymer involving the invention is, in view of enabling to exert the lipophilicity of (meth)acrylate having an alkyl group having four more carbon atoms, preferably 2,000 or more and more preferably in a range of 5,000 to 300,000.

In a planographic printing plate precursor of the invention, the content of the copolymer is, in a contained layer, in a range of 0.1 to 30 percent by mass, preferably in a range of 1 to 25 percent by mass and particularly preferably in a range of 2 to 20 percent by mass. When the addition amount of the copolymer is 0.1 percent by mass or more, an advantage thereof can be sufficiently exerted, and, the addition amount is preferably 30 percent by mass or less since the addition amount of other photosensitive component, in particular, an infrared absorbent described below is not reduced.

### [Polymer Compound]

In a photosensitive layer of the planographic printing plate precursor of the invention, separately from above-described copolymer, a polymer compound is preferably contained. Preferable examples of the polymer compounds are as follows, but the invention is not limeted them.

The polymer compound used in the invention is, in view of securing the developability, preferably a polymer compound high in the alkali solubility or the swelling property. As such polymer compounds, polymer compounds having an acidic group cited in (1) to (6) shown below in a main chain and/or a side chain of a polymer can be cited.
(1) Phenol group (—Ar—OH),
(2) sulfoneamide group (—SO₂NH—R),
(3) substituted sulfoneamide base acid group (hereinafter, referred to as “active imide group”) [—SO₂NHCOR, —SO₂NHSO₂R, —CONHSO₂R],
(4) carboxylic acid group (—CO₂H),
(5) sulfonic acid group (—SO₃H) and
(6) phosphoric acid group (—OPO₃H₂).

In (1) to (6), Ar representes a divalent aryl linking group that may have a substituent and R representes a hydrocarbon group that may have a substituent.

Examples of the polymer compounds having an acidic group selected from the (1) to (6) include ones cited below.
(1) Examples of polymer compounds having a phenol group include novolak resins, xylenol resins and resol resins, and, specifically, a phenol formaldehyde resin, a m-cresol formaldehyde resin, a p-cresol formaldehyde resin, a m-/p-mixed cresol formaldehyde resin, a phenol/cresol (any one of m-, p-, o-, m-/p-mixture, m-/o-mixture and o-/p-mixture) mixed formaldehyde resin, a 1,2-xylenol resin, a 1,3-xylenol resin, a 1,4-xylenol resin, a 1,5-xylenol resin, a 2,3-xylenol resin, a 2,4-xylenol resin, a xylenol/phenol mixed resin, a xylenol/novolak mixed resin, a xylenol/novolak/phenol mixed resin and a polycondensate of pyrogallol and acetone. Furthermore, polymer compounds obtained by copolymerizing a compound having a phenol group on a side chain can be cited. Examples thereof include polymer compounds that contain acrylamide, methacrylamide, acrylic acid ester, methacrylic acid ester or hydroxy styrene, which have a phenol group, as a copolymerizing component.
(2) As polymer compounds having a sulfoneamide group, for instance, polymers constituted with a minimum constituent unit derived from a compound having a sulfone amide group as a main constituent can be cited. As such compounds, compounds that have a sulfoneamide group where at least one hydrogen atom is bonded to a nitrogen atom and a polymerizable unsaturated group respectively at least one in a molecule can be cited. Among these, low molecular weight compounds that have an acryloyl group, allyl group or vinyloxy group and a substituted or mono-substituted aminosulfonyl group or a substituted sulfonylimino group in a molecule are preferred, and, for instance, compounds that are described in a section of polymerizing monomer having a sulfoneamide group and represented by the formulas (i) to (v) can be cited.

Among the compounds represented by the formulas (i) to (v), which are preferably used as the polymer compound having a sulfoneamide group, in the planographic printing plate precursor of the invention, in particular, m-aminosulfonylphenyl methacrylate, N-(p-aminosulfonylphenyl)methacrylamide and N-(p-aminosulfonylphenyl)acrylamide can be preferably used.
(3) Examples of the polymer compound having an active imide group include compounds each having in the molecule thereof one or more active imide groups represented by the above-mentioned structural formula and one or more unsaturated groups which can be polymerized with the active imide group(s). Of these compounds, preferable are compounds each having in the molecule thereof one or more active imide groups represented by the following structural formula and one or more unsaturated groups which can be polymerized with the active imide group(s):

Specifically, N-(p-toluenesulfonyl)methacrylamide, N-(p-toluenesulfonyl)acrylamide and others can be preferably used.
(4) Examples of the polymer compound having a carboxylic acid group include compounds each having in the molecule thereof one or more carboxylic acid groups and one or more unsaturated groups which can be polymerized with the carboxylic acid group(s). In the present invention acrylic acid, methacrylic acid and itaconic acid can be preferably used.
(5) As the polymer compound having a sulfonic acid group, for instance, polymers having a minimum constituent unit derived from a compound that has a sulfonic acid group and a polymerizable unsaturated group respectively at least one in a molecule as a main constituent unit can be cited.
(6) As the polymer compound having a phosphoric acid group, for instance, polymers having a minimum constituent unit derived from a compound that has a phosphoric acid group and a polymerizable unsaturated group respectively at least one in a molecule as a main constituent unit can be cited.

Other than the polymer compounds mentioned above, polymers that use an unsaturated compound that has an acidic group of (1) to (6) on a side chain and a urea bond as a linking group can be used.

Among the polymer compounds that have an acidic group selected from the (1) to (6), a polymer compound having (1) a phenol group, (2) a sulfoneamide group, (3) an active imide group or (4) a carboxylic acid group is preferred, in particular, a polymer compound having (1) a phenol group, (2) a sulfoneamide group or (4) a carboxylic acid group being most preferred.

Furthermore, in the polymer compound, the minimum constituent unit having an acidic group selected from the (1) to (6) is not necessarily restricted to one kind. Ones obtained by copolymerizing at least two kinds of the minimum constituent units having the same acidic group or at least two kinds of the minimum constituent units having different acidic groups may be used.

When the polymer compound is a copolymer, a copolymerizing compound having an acidic group selected from the (1) to (6) is contained, in a copolymer, preferably 3 mole percent or more of the copolymer and more preferably 5 mole percentage or more. When it is contained less than 3 mole percent, the solubility to an alkaline developing solution that does not substantially contain a solvent is lowered.

As the monomer component that is copolymerized with the polymerizing monomer having an acidic group, for instance, monomers cited in (m1) to (m11) can be used without restricting thereto.

(m1) Acrylic acid esters and methacrylic acid esters having aliphatic hydroxyl groups such as 2-hydroxyethyl acrylate or 2-hydroxyethyl methacrylate.

(m2) Alkyl acrylate such as methyl acrylate, ethyl acrylate, propyl acrylate, butyl acrylate, amyl acrylate, hexyl acrylate, octyl acrylate, benzyl acrylate, 2-chloroethyl acrylate, and glycidyl acrylate.

(m3) Alkyl methacrylate such as methyl methacrylate, ethyl methacrylate, propyl methacrylate, butyl methacrylate, amyl methacrylate, hexyl methacrylate, cyclohexyl methacrylate, benzyl methacrylate, 2-chloroethyl methacrylate, and glycidyl methacrylate.

(m4) Acrylamide or methacrylamide such as acrylamide, methacrylamide, N-methylol acrylamide, N-ethylacrylamide, N-hexylmethacrylamide, N-cyclohexylacrylamide, N-hydroxyethylacrylamide, N-phenylacrylamide, N-nitrophenylacrylamide, and N-ethyl-N-phenylacxrylamide.

(m5) Vinyl ethers such as ethyl vinyl ether, 2-chloroethyl vinyl ether, hydroxyethyl vinyl ether, propyl vinyl ether, butyl vinyl ether, octyl vinyl ether, and phenyl vinyl ether.

(m6) Vinyl esters such as vinyl acetate, vinyl chloroacetate, vinyl butylate, and vinyl benzoate.

(m7) Styrenes such as styrene, α-methylstyrene, methylstyrene, and chloromethylstyrene.

(m8) Vinyl ketones such as methyl vinyl ketone, ethyl vinyl ketone, propyl vinyl ketone, and phenyl vinyl ketone.

(m9) Olefins such as ethylene, propylene, isobutylene, butadiene, and isoprene.

(m10) N-vinylpyrrolidone, acrylonitrile, and methacrylonitrile.

(m11) Unsaturated imides such as maleimide, N-phenylmaleimide, N-acryloylacrylamide, N-acetylmethacrylamide, N-propionylmethacrylamide, and N-(p-chlorobenzoyl)methacrylamide.

As the polymer compound in the invention, different two or more kinds of polymer compounds may be used together.

Among the polymer compounds exemplified above, novolac resins and xylenol resins can be preferably used and a phenol formaldehyde resin, a m-cresol formaldehyde resin, a p-cresol formaldehyde resin, a m-/p-mixed cresol formaldehyde resin, a phenol/cresol (any one of m-, p-, o-, m-/p-mixture, m-/o-mixture and o-/p-mixture) mixed formaldehyde resin, a 1,2-xylenol resin, a 1,3-xylenol resin, a 1,4-xylenol resin, a 1,5-xylenol resin, a 2,3-xylenol resin, a 2,4-xylenol resin, a xylenol/phenol mixed resin, a xylenol/novolak mixed resin and a xylenol/novolak/phenol resin can be cited.

Furthermore, a polymer compound that has a sulfoneamide group or a carboxylic group can be preferably used and is preferably a copolymer. As the copolymer component thereof, although alkyl (meth)acrylate, (meth)acrylamide and (meth)acrylonitrile are preferably used, in addition thereto, the monomer components described above may be slightly contained. Furthermore, a copolymer having maleimide such as N-phenyl maleimide as a constituent element can be particularly preferably used as a polymer compound and, as a copolymerization component thereof, although alkyl (meth)acrylate, (meth)acrylamide and (meth)acrylonitrile are used, other aforementioned monomer components may be slightly contained.

When, in the invention, the polymer compound is a resin such as a phenol formaldehyde resin or a cresol aldehyde resin, it is preferred that the weight average molecular weight is in a range of 500 to 20,000 and the number average molecular weight is in a range of 200 to 10,000. When the polymer compound of the invention is one other than the above-mentioned resin, the polymer compound that has the weight average molecular weight of 2,000 or more and the number average molecular weight of 500 or more is preferred and the polymer compound that has the weight average molecular weight in a range of 5,000 to 300,000, the number average molecular weight in a range of 800 to 250,000, and a degree of dispersion (weight average molecular weight/number average molecular weight) in a range of 1.1 to 10 is more preferred.

In the invention, the addition amount of the polymer compound in a photosensitive layer is preferably in a range of 30 to 99 percent by mass, more preferably in a range of 50 to 99 percent by mass and particularly preferably in a range of 65 to 99 percent by mass. When the addition amount of the polymer compound is 30 percent by mass or more, the endurance of the photosensitive layer is improved and, when the addition amount of the polymer compound is 99 percent by mass or less, without reducing an addition amount of an infrared absorbent described below, sufficient sensitivity can be obtained.

### [Infrared Absorbent]

As an infrared absorbent, various kinds of known pigments and dyes can be cited. As the pigment, commercially available pigments and pigments described in the Color Index (C. I.) Binran (Color Index Handbook), “Saishin Ganryo Binran” (edited by Nihon Ganryo Gijyutu Kyokai, 1977), “Saishin Ganryo Oyo Gijyutu” (published by CMC Publishing Co., 1986) and “Insatu Inki Gijyutu” (published by CMC Publishing Co., 1984) can be cited.

Examples of the pigment include black pigments, yellow pigments, orange pigments, brown pigments, red pigments, purple pigments, blue pigments, green pigments, fluorescent pigments, metal powder pigments, and polymer-bonded dyes. Specifically, the following can be used: insoluble azo pigments, azo lake pigments, condensed azo pigments, chelate azo pigments, phthalocyanine pigments, anthraquinone pigments, perylene and perynone pigments, thioindigo pigments, quinacridone pigments, dioxazine pigments, isoindolinone pigments, quinophthalone pigments, dyeing lake pigments, azine pigments, nitroso pigments, nitro pigments, natural pigments, fluorescent pigments, inorganic pigments, and carbon black.

These pigments may be used with or without surface treatment. Examples of surface treatment include a method of coating the surface of the pigments with resin or wax; a method of adhering a surfactant onto the surface; and a method of bonding a reactive material (such as a silane coupling agent, an epoxy compound, or a polyisocyanate) to the pigment surface. The surface treatment methods are described in “Nature and Application of Metal Soap” (Saiwai Shobo), “Printing Ink Technique” (by CMC Publishing Co., Ltd. in 1984). And “Latest Pigment Applied Technique” (by CMC Publishing Co., Ltd. in 1986.

A particle diameter of the pigment is preferably in a range of 0.01 to 10 μm, more preferably in a range of 0.05 to 1 μm and particularly preferably in a range of 0.1 to 1 μm. When the particle diameter of the pigment is more than 0.01 μm, the stability in a photosensitive coating solution of the dispersion is improved and when the particle diameter thereof is 10 μm or less, the uniformity of the photosensitive layer can be improved.

The method for dispersing the pigment may be a known dispersing technique used to produce ink or toner. Examples of a dispersing machine, which can be used, include an ultrasonic disperser, a sand mill, an attriter, a pearl mill, a super mill, a ball mill, an impeller, a disperser, a KD mill, a colloid mill, a dynatron, a three-roll mill, and a pressing kneader. Details are described in “Latest Pigment Applied Technique” (by CMC Publishing Co., Ltd. in 1986).

As the dye, commercially available dyes and known ones described in literatures (such as “Senryo Binran” (edited by Yuki Goseikagaku Kyokai, 1970) can be cited and examples thereof include azo dyes, metal complex azo dyes, pyrazolone azo dyes, anthraquinone dyes, phthalocyanine dyes, carbonium dyes, quinoneimine dyes, methine dyes and cyanine dyes. Among the pigments or dyes, pigments and dyes that absorb infrared light or near infrared light are, in view of being advantageous in the use of a laser that emits infrared light or near infrared light, particularly preferred.

As the infrared-light absorbing pigment or the near infrared-light absorbing pigment carbon black is preferably used.

Preferable examples of the infrared-light absorbing dye or near infrared-light absorbing dye include cyanine dyes described in JP-A Nos. 58-125246, 59-84356, 59-202829, and 60-78787; methine dyes described in JP-A Nos. 58-173696, 58-181690, and 58-194595; naphthoquinone dyes described in JP-A Nos. 58-112793, 58-224793, 59-48187, 59-73996, 60-52940, and 60-63744; squalirium dyes described in JP-A No. 58-112792; and cyanine dyes described in GB Patent No. 434,875.

Other preferable examples of the dye include near infrared absorbing sensitizers described in U.S. Pat. No. 5,156,938; substituted arylbenzo(thio)pyrylium salts described in U.S. Pat. No. 3,881,924; trimethinethiapyrylium salts described in JP-A No. 57-142645 (U.S. Pat. No. 4,327,169); pyrylium type compounds described in JP-A Nos. 58-181051, 58-220143, 59-41363, 59-84248, 59-84249, 59-146063, and 59-146061; cyanine dyes described in JP-A No. 59-216146; pentamethinethiopyrylium salts described in U.S. Pat. No. 4,283,475; and pyrylium compounds Epolight III-178, Epolight III-130, Epolight III-125, Epolight V-176A described in Japanese Patent Application Publication (JP-B) Nos. 5-13514 and 5-19702.

Furthermore, as the particularly preferred another examples of the dyes, near infrared absorbing dyes described as formulas (I) and (II) in U.S. Pat. No. 4,756,993 can be cited. The addition amount of the pigment or dye is preferably in a range of 0.01 to 50 percent by mass and more preferably in a range of 0.1 to 10 percent by mass of a total solid content of a printing plate material. In the case of the dye, 0.5 to 10 percent by mass is particularly preferred and, in the case of the pigment, 3.1 to 10 percent by mass is particularly preferred. When the addition amount of the pigment or dye is 0.01 percent by mass or more, sufficient sensitivity can be obtained, and, when the addition amount thereof is 50 percent by mass or less, the uniformity of a photosensitive layer is improved and sufficient durability of the photosensitive layer can be obtained.

### [Layer Configuration of Photosensitive Layer]

A photosensitive layer of a planographic printing plate precursor of the invention may be any one of a single layer configuration, a phase-separated configuration and a multilayer configuration.

As the single layer type photosensitive layer, photosensitive layers described in, for instance, JP-A No. 7-285275 and WO 97/39894 can be used; as the phase-separated type photosensitive layer, photosensitive layers described in, for instance, JP-A No. 11-44956; and as the multilayer type photosensitive layer, photosensitive layers described in JP-A No. 11-218914, U.S. Pat. Nos. 6,352,812 B1, 6,352,811 B1, 6,358,669 B1 and 6,534,238 B1 and EP No. 864420B1, but the invention is not limited to them.

Furthermore, in the case of the multilayer configuration, as far as the outermost layer of the photosensitive layer contains an infrared absorbent and a copolymer, without particularly limiting, a lower layer as well may contain an infrared absorbent. Still furthermore, when a planographic printing plate precursor of the invention contains a polymer compound, a layer that contains the polymer compound is not limited to an upper layer (the uppermost surface layer) or a lower layer and both of the upper layer and the lower layer may contain the polymer compound. In this case, polymer compounds in the upper layer and the lower layer may be the same or different ones.

### [Other Components]

In layers disposed to a planographic printing plate precursor of the invention, as needs arise, various kinds of additives may be further added. For instance, in order to adjust the solubility of a photosensitive layer, a so-called dissolution inhibitor such as another onium salt, an aromatic sulfone compound, an aromatic sulfonic acid ester compound or a polyfunctional amine compound, which, when added to the photosensitive layer, can improve the dissolution inhibition function to a developing solution of an alkali water-soluble polymer (alkali-soluble resin) is preferably added. Among these, a substance such as an onium salt, an o-quinonediazide compound or a sulfonic acid alkyl ester, which is pyrolytic and, in a non-pyrolyzed state, substantially lowers the solubility of an alkali-soluble resin is preferably used together in view of enabling to control the dissolution inhibition property to a developing solution of an image portion.

Preferable examples of the onium salt used in the invention include diazonium salts described in S. I. Schlesinger, Photogr. Sci. Eng., 18, 387 (1974), T. S. Bal et al., Polymer, 21, 423 (1980), and JP-A No. 5-158230; ammonium salts described in U.S. Pat. Nos. 4,069,055 and 4,069,056, and JP-A No. 3-140140; phosphonium salts described in D. C. Necker et al., Macromolecules, 17, 2468 (1984), C. S. Wen et al., Teh, Proc. Conf. Rad. Curing ASIA, p 478 Tokyo, October (1988), and U.S. Pat. Nos. 4,069,055 and 4,069,056; iodonium salts described in J. V. Crivello et al., Macromolecules, 10 (6), 1307 (1977), Chem. & Eng. News, November 28, p 31 (1988), EP No. 104,143, U.S. Pat. Nos. 5,041,358 and 4,491,628, and JP-A Nos. 2-150848 and 2-296514; sulfonium salts described in J. V. Crivello et al., Polymer J. 17, 73 (1985), J. V. Crivello et al., J. Org. Chem., 43, 3055 (1978), W. R. Watt et al., J. Polymer Sci., Polymer Chem. Ed., 22, 1789 (1984), J. V. Crivello et al., Polymer Bull., 14, 279 (1985), J. V. Crivello et al., Macromolecules, 14 (5), 1141 (1981), J. V. Crivello et al., J. Polymer Sci., Polymer Chem. Ed., 17, 2877 (1979), EP Nos. 370,693, 233,567, 297,443 and 297,442, U.S. Pat. Nos. 4,933,377, 3,902,114, 5,041,358, 4,491,628, 4,760,013, 4,734,444 and 2,833,827, and DE Pat. Nos. 2,904,626, 3,604,580 and 3,604,581; selenonium salts described in J. V. Crivello et al., Macromolecules, 10 (6), 1307 (1977), J. V. Crivello et al., J. Polymer Sci., Polymer Chem. Ed., 17, 1047 (1979); arsonium salts described in C. S. Wen et al., and The Proc. Conf. Rad. Curing ASIA, p 478, Tokyo, October (1988).

Among such onium salts, diazonium salts and quaternary ammonium salts are particularly preferable from the viewpoints of both their capacity of hindering dissolution, and their thermal decomposability. The diazonium salts represented by general formula (I) in the JP-A No. 5-158230 and the diazonium salts represented by general formula (1) in JP-A No. 11-143064 are more preferable, and diazonium salts represented by general formula (1) in the JP-A No. 11-143064, which have low absorption wavelength peaks within the visible ray range, are most preferable. As the quaternary ammonium salts, those represented by formulae (1) to (10) of [Ka 5] and [Ka 6] of JP-A No. 2002-229186 are preferable. As the sulfonium salt those represented by formula (II) of [ka 2] in the JP-A No. 2005-266003 are preferable.

Examples of the counter ion of the onium salt include tetrafluoroboric acid, hexafluorophosphoric acid, triisopropylnaphthalenesulfonic acid, 5-nitro-o-toluenesulfonic acid, 5-sulfosalicylic acid, 2,5-dimethylbenzenesulfonic acid, 2,4,6-trimethylbenzenesulfonic acid, 2-nitrobenzenesulfonic acid, 3-chlorobenzenesulfonic acid, 3-bromobenzenesulfonic acid, 2-fluorocaprylnaphthalenesulfonic acid, dodecylbenzenesulfonic acid, 1-naphthol-5-sulfonic acid, 2-methoxy-4-hydroxy-5-benzoyl-benzenesulfonic acid, and p-toluenesulfonic acid. Among these examples, hexafluorophosphoric acid, and alkylaromatic sulfonic acids such as triisopropylnaphthalenesulfonic acid, 2,5-dimethylbezenesulfonic acid and 2-methoxy-4-hydroxy-5-benzoyl benzenesulfonic acid are particularly preferable.

The quinonediazide is preferably an o-quinonediazide compound. The o-quinonediazide compound used in the invention is a compound having at least one o-quinonediazide group and having an alkali-solubility increased by being thermally decomposed. The compound may be any one of compounds having various structures. In other words, the o-quinonediazide compound assists the solubility of the photosensitive material both from the viewpoint of the effects of being thermally decomposed, and thereby losing the function of suppressing the dissolution of the binder, and the effect that the o-quinonediazide itself is changed into an alkali-soluble material.

Preferable examples of the o-quinonediazide compound used in the invention include compounds described in J. Coser, “Light-Sensitive Systems” (John Wiley & Sons. Inc.), pp. 339-352. Particularly preferable are sulfonic acid esters or sulfonamides of o-quinonediazide made to react with various aromatic polyhydroxy compounds or with aromatic amino compounds.

Further preferable examples include an ester made from benzoquinone-(1,2)-diazidesulfonic acid chloride or naphthoquinone-(1,2)-diazide-5-sulfonic acid chloride and pyrogallol-acetone resin, as described in JP-B No. 43-28403; and an ester made from benzoquinone-(1,2)-diazidesulfonic acid chloride or naphthoquinone-(1,2)-diazide-5-sulfonic acid chloride and phenol-formaldehyde resin.

Additional preferable examples include an ester made from naphthoquinone-(1,2)-diazide-4-sulfonic acid chloride and phenol-formaldehyde resin or cresol-formaldehyde resin; and an ester made from naphthoquinone-(1,2)-diazide-4-sulfonic acid chloride and pyrogallol-acetone resin.

Other useful o-quinonediazide compounds are reported in unexamined or examined patent documents, examples of which include JP-A Nos. 47-5303, 48-63802, 48-63803, 48-96575,49-38701 and 48-13354, JP-B No. 41-11222, 45-9610 and 49-17481, U.S. Pat. Nos. 2,797,213, 3,454,400, 3,544,323, 3,573,917, 3,674,495 and 3,785,825, GB Patent Nos. 1,227,602, 1,251,345, 1,267,005, 1,329,888 and 1,330,932, and DE Pat. No. 854,890.

The amount of onium salt and/or o-quinonediazide compound added as the decomposable dissolution suppresser(s) is preferably from 1 to 10%, more preferably from 1 to 5%, and even more preferably from 1 to 2% by relative to the total solid contents of the recording layer. The onium salts and the o-quinonediazide compounds may be used either independently or in the form of mixtures of two or more thereof.

The amount of additives other than the o-quinonediazide compound added is preferably from 0.1 to 5%, more preferably from 0.1 to 2%, and even more preferably from 0.1 to 1.5% by mass. The additives and the binder used in the invention are preferably incorporated into the same layer.

A dissolution suppresser having no decomposability may be used in combination. Preferable examples thereof include sulfonic acid esters, phosphoric acid esters, aromatic carboxylic acid esters, aromatic disulfones, carboxylic acid anhydrides, aromatic ketones, aromatic aldehydes, aromatic amines, and aromatic ethers, details of which are described in JP-A No. 10-268512; acidic color-developable dyes which have a lactone skeleton, an N,N-diarylamide skeleton or a diarylmethylimino skeleton and also function as a coloring agent, details of which are described in JP-A No. 11-190903; and nonionic surfactants described, details of which are described in JP-A No. 2000-105454. In order to enhance sensitivity, the planographic printing plate precursor of the present invention may also contain a cyclic acid anhydride, a phenolic compound, or an organic acid.

Examples of cyclic acid anhydride include phthalic anhydride, tetrahydrophthalic anhydride, hexahydrophthalic anhydride, 3,6-endooxy-4-tetrahydrophthalic anhydride, tetrachlorophthalic anhydride, maleic anhydride, chloromaleic anhydride, α-phenylmaleic anhydride, succinic anhydride, and pyromellitic anhydride which are described in U.S. Pat. No. 4,115,128.

Examples of phenolic compound include bisphenol A, p-nitrophenol, p-ethoxyphenol, 2,4,4′-trihydroxybenzophenone, 2,3,4-trihydroxybenzophenone, 4-hydroxybenzophenone, 4,4′,4″-trihydroxytriphenylmethane, 4,4′,3″,4″-tetrahydroxy-3,5,3′,5′-tetramethyltriphenylmethane.

Examples of the organic acid include sulfonic acids, sulfonic acids, alkylsulfuric acids, phosphonic acids, phosphates, and carboxylic acids, which are described in JP-A No. 60-88942 or 2-96755.

When the cyclic acid anhydride, the phenol or the organic acid is added to a photosensitive layer of a planographic printing plate precursor, the amount thereof is preferably from 0.05 to 20%, more preferably from 0.1 to 15%, and even more preferably from 0.1 to 10% by mass of the recording layer.

Furthermore, other than the above-mentioned ones, an epoxy compound, vinyl ethers, a phenol compound having a hydroxymethyl group or a phenol compound having an alkoxymethyl group described in JP-A No. 8-276558 or a crosslinking compound having the alkali dissolution inhibition action described in JP-A No. 11-160860 previously submitted by the present inventors can be, as needs arise, appropriately added.

Still furthermore, a printing agent for obtaining a visible image immediately after the heating due to exposure or a dye or a pigment as an image coloring agent may be added.

A typical example of a printing-out agent is a combination of a compound which is heated by exposure to light, thereby emitting an acid (an optically acid-generating agent), and an organic dye which can form salts (salt formable organic dye).

Specific examples thereof include combinations of an o-naphthoquinonediazide-4-sulfonic acid halogenide with a salt-formable organic dye, described in JP-A Nos. 50-36209 and 53-8128; and combinations of a trihalomethyl compound with a salt-formable organic dye, described in each of JP-A Nos. 53-36223, 54-74728, 60-3626, 61-143748, 61-151644 and 63-58440.

The trihalomethyl compound is classified into an oxazol compound or a triazine compound. Both of the compounds provide excellent in stability over the passage of time and produce a vivid printed-out image.

As the image coloring agent, a dye different from the above-mentioned salt-formable organic dye may be used. Preferable examples of such a dye, and of the salt-formable organic dye, include oil-soluble dyes and basic dyes.

Specific examples thereof include Oil yellow #101, Oil Yellow #103, Oil Pink #312, Oil Green BG; Oil Blue BOS, Oil Blue #603, Oil Black BY, Oil Black BS, and Oil Black T-505 (each of which is manufactured by Orient Chemical Industries Ltd.); Victoria Pure Blue, Crystal Violet (CI42555), Methyl Violet (CI42535), Ethyl Violet, Rhodamine B (CI145170B), Malachite Green (CI42000), and Methylene Blue (CI52015).

Dyes described in JP-A No. 62-293247 are particularly preferable. These dyes may be added to the photosensitive layer at a ratio of 0.01 to 10% by mass, and preferably 0.1 to 3% by mass, relative to the total solid contents therein.

Whenever necessary, a plasticizer may be added to the planographic printing plate preccursor of the invention to give flexibility to a coating film made from the composition. Examples of the plasticizer include oligomers and polymers of butyl phthalyl, polyethylene glycol, tributyl citrate, diethyl phthalate, dibutyl phthalate, dihexyl phthalate, dioctyl phthalate, tricresyl phosphate, tributyl phosphate, trioctyl phosphate, tetrahydrofurfuryl olete, and acrylic acid and methacrylic acid.

### [Coating Solvent]

A planographic printing plate precursor of the invention can be prepared when the components are dissolved in a solvent, followed by coating on a support, further followed by drying to dispose a photosensitive layer. Examples of the coating solvents used here include methanol, ethanol, n-propanol, isopropyl alcohol, n-butanol, sec-butanol, isobutanol, 2-methyl-1-butanol, 3-methyl-1-butanol, 2-methyl-2-butanol, 2-ethyl-1-butanol, 1-pentanol, 2-pentanol, 3-pentanol, n-hexanol, 2-hexanol, cyclohexanol, methyl cyclohexanol, 1-heptanol, 2-heptanol, 3-heptanol, 1-octanol, 4-methyl-2-pentanol, 2-hexyl alcohol, benzyl alcohol, ethylene glycol, diethylene glycol, triethylene glycol, tetraethylene glycol, 1,3-propanediol, 1,5-pentane glycol, dimethyl triglycol, furfuryl alcohol, hexylene glycol, hexyl ether, 3-methoxy-1-butanol, 3-methoxy-3-methyl butanol, butyl phenyl ether, ethylene glycol monoacetate, 2-methoxy ethanol, 2-ethoxy ethanol, propylene glycol monomethyl ether, propylene glycol monoethyl ether, propylene glycol monopropyl ether, propylene glycol monobutyl ether, propylene glycol phenyl ether, dipropylene glycol monomethyl ether, dipropylene glycol monoethyl ether, dipropylene glycol monopropyl ether, dipropylene glycol monobutyl ether, tripropylene glycol monomethyl ether, methyl carbitol, ethyl carbitol, ethyl carbitol acetate, butyl carbitol, triethylene glycol monomethyl ether, triethylene glycol monoethyl ether, tetraethylene glycol dimethyl ether, diacetone alcohol, acetophenone, cyclohexanone, methyl cyclohexanone, acetonyl acetone, isophorone, methyl lactate, ethyl lactate, butyl lactate, propylene carbonate, phenyl acetate, sec-butyl acetate, cyclohexyl acetate, diethyl oxalate, methyl benzoate, ethyl benzoate, γ-butylolactone, 3-methoxy-1-butanol, 4-methoxy-1-butanol, 3-ethoxy-1-butanol, 3-methoxy-3-methyl-1-butanol, 3-methoxy-3-ethyl-1-pentanol, 4-ethoxy-1-pentanol, 5-methoxy-1-hexanol, 4-hydroxy-2-pentanone, 5-hydroxy-2-pentanone, 6-hydroxy-2-pentanone, 4-hydroxy-3-pentanone, 6-hydroxy-2-hexanone, 3-methyl-3-hydroxy-2-pentanone, methyl cellosolve (MC), ethyl cellosolve (EC), allyl alcohol, isopropyl ether, butyl ether, anisole, propylene glycol monomethyl ether acetate, diethyl carbitol, tetrahydrofuran, dioxane, dioxolane, acetone, methyl propyl ketone, methyl ethyl ketone, methyl amyl ketone, diethyl ketone, ethyl butyl ketone, dipropyl ketone, diisobutyl ketone, 3-hydroxy-2-butanone, 4-hydroxy-2-butanone, 2-methoxyethyl acetate, 2-ethoxyethyl acetate, methoxybutyl acetate, methyl propionate, ethyl propionate, propyl propionate, methyl butyrate, ethyl butyrate, butyl butyrate, N-methyl-2-pyrolidone, acetonitrile, dimethyl formamide (DMF), dimethyl acetamide (DMAc), n-pentane, 2-methyl pentane, 3-ethyl pentane, methyl cyclopentane, n-hexane, isohexane, cyclohexane, methylcyclohexane, n-heptane, cycloheptane, n-octane, isooctane, nonane, decane, benzene, toluene, o-xylene, m-xylene, p-xylene, ethyl benzene, o-diethyl benzene, m-diethyl benzene, p-diethyl benzene, cumene, n-amyl benzene, dimethylsulfoxide (DMSO) and dimethyl diglycol (DMDG). These solvents may be used singularly or in a combination of at least two kinds thereof. In a photosensitive composition solution that uses the (mixed) solvent, a concentration of a total solid content in the solvent is preferably in a range of 1 to 50 percent by mass and more preferably in a range of 1 to 30 percent by mass.

### [Coating Method and So On]

A planographic printing plate precursor of the invention can be produced by coating the photosensitive composition solution on an appropriate support. However, as needs arise, a protective layer, a resin intermediate layer and a backcoat layer, which will be described below, can be similarly formed.

A coated amount of a solid content, which is obtained after coating and drying, is, in the case of a single layer, preferably in a range of 0.3 to 5.0 g/m² and more preferably in a range of 0.5 to 3.0 g/m². In the case of a multilayer, an upper layer and a lower layer, respectively, are preferably in a range of 0.05 to 2.0 g/m² and in a range of 0.3 to 5.0 g/m² and more preferably in a range of 0.1 to 1.0 g/m² and in a range of 0.5 to 3.0 g/m². Furthermore, a mass ratio (upper layer/lower layer) of coated amounts of the upper layer and the lower layer is preferably in a range of 0.05 to 1 and more preferably in a range of 0.1 to 0.8.

Various methods may be used for applying the recording layer coating solution. Examples thereof include bar coater coating, spin coating, spray coating, curtain coating, dip coating, air knife coating, blade coating, roll coating, and the like. As the coating amount decreases, the apparent sensitivity increases, but the film properties of the photosensitive layer deteriorates.

### [Support]

As a support used in a planographic printing plate precursor of the invention, as far as it has a hydrophilic surface, there is no particular restriction, and one that is a dimensionally stable plate and satisfies necessary physical properties such as the strength and flexibility can be preferably used. Examples thereof include metal-laminated or metal-deposited paper or plastic films such as paper, plastics (such as polyethylene, polypropylene or polystyrene)-laminated paper, a plate of metal (such as aluminum, zinc or copper), a film of plastics (such as cellulose diacetate, cellulose triacetate, cellulose propionate, cellulose butyrate, cellulose acetate butyrate, cellulose nitrate, polyethylene terephthalate, polyethylene, polystyrene, polypropylene, polycarbonate or polyvinyl acetal). The hydrophilic surface means a support surface obtained by applying an anodic oxidation process, a hydrophilization process or a combination thereof, which will be described below.

The support is preferably a polyester film or an aluminum plate, and more preferably an aluminum plate, since an aluminum plate is superior in terms of dimensional stability and is also relatively inexpensive.

Preferable examples of the aluminum plate include a pure aluminum plate and alloy plates made of aluminum as a main component with a very small amount of other elements. A plastic film on which aluminum is laminated or vapor-deposited may also be used.

Examples of other elements contained in the aluminum alloys include silicon, iron, manganese, copper, magnesium, chromium, zinc, bismuth, nickel, and titanium. The content by percentage of different elements in the alloy is at most 10% by mass. A particularly preferable aluminum plate in the invention is a pure aluminum plate; however, since from the viewpoint of refining a completely pure aluminum cannot be easily produced, a very small amount of other elements may also be contained in the plate.

The aluminum plate used as the support is not specified in terms of the composition thereof. Thus, aluminum plates which are conventionally known can be appropriately used. The thickness of the aluminum plate used in the invention is preferably from about 0.1 to 0.6 mm, and more preferably from 0.12 to 0.4 mm.

If necessary, prior to the surface-roughening treatment, the aluminum plate may optionally be subjected to degreasing treatment, in order to remove rolling oil or the like on the surface, with a surfactant, an organic solvent, an aqueous alkaline solution or the like. The surface-roughening treatment of the aluminum surface can be performed by various methods such as a mechanical surface-roughening method, a method of dissolving and roughening the surface electrochemically, and a method of dissolving the surface selectively in a chemical manner.

Mechanical surface-roughening methods which can be used may be known methods, such as a ball polishing method, a brush polishing method, a blast polishing method or a buff polishing method. An electrochemical surface-roughening method may be a method of performing surface-roughening in an electrolyte of hydrochloric acid or nitric acid, by use of an alternating current or a direct current. As disclosed in JP-A No. 54-63902, a combination of the two kinds of methods may be used.

Thus surface-roughened aluminum plate, as needs arise, is alkali etched and neutralized, followed by, as needs arise, subjecting to the anodic oxidation process to heighten the water retention property and the wear resistance of the surface. As an electrolyte used in the anodic oxidation process of an aluminum plate, various kinds of electrolytes that form a porous oxide film can be used. In general, sulfuric acid, phosphoric acid, oxalic acid, chromic acid or a mixture thereof is used. A concentration of the electrolyte is appropriately determined depending on a kind of the electrolyte. Treatment conditions for anodization cannot be specified as a general rule since conditions vary depending on the electrolyte used; however, the following range of conditions are generally suitable: an electrolyte concentration of 1 to 80% by mass, a solution temperature of 5 to 70° C., a current density of 5 to 60 A/dm2, a voltage of 1 to 100 V, and an electrolyzing time of 10 seconds to 5 minutes. If the amount of anodic oxide film is less than 1.0 g/m2, printing resistance is inadequate or non-image portions of the planographic printing plate tend to become easily damaged and the so-called “blemish stains”, resulting from ink adhering to damaged portions at the time of printing, are easily generated.

After the anodizing treatment, the surface of the aluminum is if necessary subjected to treatment for obtaining hydrophilicity. This securance of hydrophilicity treatment may be an alkali metal silicate (for example, an aqueous sodium silicate solution) method, as disclosed in U.S. Pat. Nos. 2,714,066, 3,181,461, 3,280,734, and 3,902,734. In this method, the support is subjected to an immersing treatment or an electrolyzing treatment with an aqueous sodium silicate solution. In addition, the following methods may also be used: a method of treating the support with potassium fluorozirconate, as disclosed in JP-B No. 36-22063, or with polyvinyl phosphonic acid, as disclosed in U.S. Pat. Nos. 3,276,868, 4,153,461, and 4,689,272.

### (Undercoat Layer)

The planographic printing plate precursor according to the present invention is a plate having a photosensitive layer as described above provided on a support, and an undercoat layer may be formed as needed between the support and the photosensitive layer.

When formed, the undercoat layer between the support and the photosensitive layer functions as a heat-insulating layer, inhibiting diffusion of the heat generated by exposure to an infrared laser to the support and allowing more efficient use of an infrared laser, and thus, is advantageous in improving sensitivity. When forming the undercoat layer, the photosensitive layer according to the invention is positioned on the exposure face or in the vicinity thereof, and thus significantly retains its sensitivity to an infrared laser.

Also in the unexposed areas, the photosensitive layer, which is resistant to penetration of the alkaline developer, functions as a protective layer for the undercoat layer, improving development stability, forming an image having superior discrimination, and ensuring image stability over time. The undercoat layer is a layer containing an alkali-soluble polymer as its principal component and is extremely soluble in the developer. If the undercoat layer is formed close to the support, the exposed area, where the components in the photosensitive layer that becomes more soluble by exposure, is dissolved or dispersed in the developer more readily without generation of undissolved film, for example, when a less active developer is used, which seems to be effective for improving developing efficiency. For that reason, the undercoat layer is thought to be useful.

Various organic compounds may be used as the components for the undercoat layer, and examples thereof include amino group-containing phosphonic acids that may be substituted such as carboxymethylcellulose, dextrin, gum arabic, and 2-aminoethylphosphonic acid; organic phosphonic acid that may be substituted such as phenylphosphonic acid, naphthylphosphonic acid, alkylphosphonic acids, glycerophosphonic acid, methylenediphosphonic acid and ethylenediphosphonic acid; organic phosphoric acids that may be substituted such as phenylphosphoric acid, naphthylphosphoric acid, alkylphosphoric acid and glycerophosphoric acid; organic phosphinic acids such as phenylphosphinic acid, naphthylphosphinic acid, alkylphosphinic acid and glycerophosphinic acid; amino acids such as glycine and β-alanine; hydroxy group-containing amine hydrochloride salts such as triethanolamine hydrochloride salt; and the like. These compounds may be used in combinations of two or more.

An undercoat layer containing at least one compound selected from the group consisting of organic polymer compounds having the structural unit represented by the following Formula is also preferable.

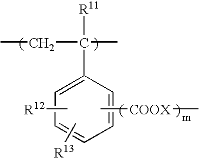

In the Formula above, R¹¹ represents a hydrogen or halogen atom or an alkyl group; R¹² and R¹³ each independently represent a hydrogen atom, a hydroxyl group, a halogen atom, an alkyl group, a substituted alkyl group, an aryl group, a substituted aryl group, —OR¹⁴, —COOR¹⁵, —CONHR¹⁶, —COR¹⁷ or —CN, or R¹² and R¹³ may bind to each other forming a ring; R¹⁴ to R¹⁷ each independently represent an alkyl or aryl group; X represents a hydrogen or metal atom, or NR¹⁸R¹⁹R²⁰R²¹; R¹⁸ to R²¹ each independently represent a hydrogen atom, an alkyl group, a substituted alkyl group, an aryl group or a substituted aryl group, or R¹⁸ and R¹⁹ may bind to each other forming a ring; and m represents an integer of 1 to 3.

An example of a suitable undercoat layer component for the planographic printing plate precursor according to the invention is a polymer compound having an acid group-containing a structural component and an onium group-containing component described in JP-A No. 2000-241962. Specifically, it is a copolymer of an acid group-containing monomer and an onium group-containing monomer. The acid group is preferably an acid group having an acid dissociation constant (pKa) of 7 or more, more preferably —COOH, —SO₃H, —OSO₃H, —PO₃H₂, —OPO₃H₂, —CONHSO₂—, or —SO₂NHSO₂—, and particularly preferably —COOH.

Specific examples of the acid group-containing monomers include acrylic acid, methacrylic acid, crotonic acid, isocrotonic acid, itaconic acid, maleic acid, maleic anhydride, styrene derivatives having the acid group above, and the like. The onium salt is preferably an onium group having an atom in groups V and VI of the Periodic Table, more preferably an onium salt of a nitrogen, phosphorus or sulfur atom, and particularly preferably an onium salt of a nitrogen atom. Specific examples of the onium salt-containing monomers include methacrylates and methacrylamides having an ammonium group on the side chain, and styrenes having an onium group-containing substituent such as those having a quaternary ammonium group.

In addition, the compounds described in JP-A Nos. 2000-108538, 2002-257484, and 2003-78699, and others may be used as needed.

Such an undercoat layer can be formed, for example, according to the following methods: a method of dissolving the organic compounds in an organic solvent or a mixed solvent of water, methanol, ethanol, methylethylketone, or the like, and applying and drying the solution on an aluminum plate (support); and a method of dissolving the organic compounds in an organic solvent or a mixed solvent of water, methanol, ethanol, methylethylketone, or the like, allowing an aluminum plate (support) to absorb the solution by immersion in the solution, and washing the plate with water or the like and drying it.

In the former method, it is possible to apply the solution of the organic compound at a concentration of 0.005 to 10 wt % by various methods.

Alternatively, in the latter method, the concentration of the solution is 0.01 to 20 wt %, preferably 0.05 to 5 wt %; the immersion temperature is 20 to 90° C., preferably 25 to 50° C.; an the immersion period is 0.1 second to 20 minutes, preferably 2 seconds to 1 minutes. The solution used may be adjusted to a pH in a range of 1 to 12 by addition of a basic substance such as ammonia, triethylamine, or potassium hydroxide, or an acidic substance such as hydrochloric acid or phosphoric acid. A yellow dye may also be added, for improvement of tone reproducibility in the image-recording material.

A coated amount of an undercoat layer is preferably in a range of 2 to 200 mg/m² and more preferably in a range of 5 to 100 mg/m². When the coated amount is 2 mg/m² or more, sufficient press life can be obtained. When the coated amount is 200 mg/m² or less as well, the situation is the same.

### (Exposure)

An image is formed thermally on the planographic printing plate precursor according to the present invention. Specifically, direct image recording with a thermal recording head or the like, scanning exposure with an infrared laser, high-illumination flash exposure with xenon discharge lamp or the like, infrared lamp exposure, or the like is used for this image formation, but exposure to a high-output infrared solid laser emitting a light at a wavelength of 700 to 1,200 nm, such as from an infrared light-emitting semiconductor laser or YAG laser is suitable.

The laser output is preferably 100 mW or more, and it is preferable to use a multi-beam laser device to shorten the exposure period. The exposure period per pixel is preferably 20 μsec or less, and the irradiation energy applied onto the recording material is preferably 10 to 500 mJ/cm².

### [Development]

In the invention, an exposed photosensitive planographic printing plate precursor is preferably developed by an alkaline aqueous solution that does not substantially contain an organic solvent and has the pH of 12 or more. Here, “does not substantially contain an organic solvent” means that an organic solvent is not contained to an extent that causes an inconvenience from the viewpoints of environmental health, safety and workability. However, in the invention, it means that a ratio of the organic solvent in the developing solution is 0.5 percent by mass or less and preferably 0.3 percent by mass or less and most preferably zero. Furthermore, the pH thereof is preferably 12.0 or more and more preferably in a range of 12.0 to 14.0.

As the developer (hereinafter this term will represent a developer including a replenisher), a conventionally known aqueous alkali solution may be used. Examples of the alkali agent include inorganic alkali salts such as sodium silicate, potassium silicate, trisodium phosphate, tripotassium phosphate, triammonium phosphate, disodium hydrogenphosphate, dipotassium hydrogenphosphate, diammonium hydrogenphosphate, sodium carbonate, potassium carbonate, ammonium carbonate, sodium hydrogencarbonate, potassium hydrogencarbonate, ammonium hydrogen carbonate, sodium borate, potassium borate, ammonium borate, sodium hydroxide, ammonium hydroxide, potassium hydroxide and lithium hydroxide; and organic alkali agents such as monomethylamine, dimethylamine, trimethylamine, monoethylamine, diethylamine, triethylamine, monoisopropylamine, diisopropylamine, triisopropylamine, n-butylamine, monoethanolamine, diethanolamine, triethanolamine, monoisopropanolamine, diisopropanolamine, ethyleneimine, ethylenediamine, and pyridine. These alkali agents may be used alone or in combinations of two or more thereof.

Among the above aqueous alkali solutions, one developer which exerts the effect of the invention is an aqueous solution of a pH 12 or higher so-called “silicate developer” containing alkali silicate as a base, or containing alkali silicate obtained by mixing a base with a silicon compound, and the other more preferable developer is a so-called “non-silicate developer” which does not contain alkali silicate, and contains a non-reducing sugar (organic compound having buffering action) and a base.

In the former, developability of an aqueous solution of alkali metal silicate can be regulated by a ratio (generally represented by mole ratio of [SiO₂]/[M₂O]) of silicon oxide SiO₂ and alkali metal oxide M₂O. For example, an aqueous solution of sodium silicate in which a mole ratio of SiO₂/Na₂O is 1.0 to 1.5 (that is, [SiO₂]/[Na₂O] is 1.0 to 1.5), and a content of SiO₂ is 1 to 4% by mass as disclosed in JP-A No. 54-62004, and an aqueous solution of alkali metal silicate in which [SiO₂]/[M] is 0.5 to 0.75 (that is, [SiO₂]/[M₂O] is 1.0 to 1.5), a concentration of SiO₂ is 1 to 4% by mass, and the developer contains at least 20% potassium using gram atom of a total alkali metal present therein as a standard, as described in Japanese Patent Application Publication (JP-B) No. 57-7427 are preferably used.

Furthermore, a so-called “non-silicate developing solution” that does not contain alkali silicate and contains a non-reducing sugar and a base can be also preferably used. In this case, a non-reducing sugar that has the buffering property for inhibiting the pH from varying is preferably contained. The non-reducing sugars are sugars that neither have a free aldehyde group and ketone group nor show the reducing property and can be categorized into a trehalose type oligosaccharide where reducing groups are bonded each other, a glycoside where a reducing group of sugar and a non-sugar are bonded, and a sugar alcohol obtained by adding hydrogen to a sugar to reduce. Any one thereof can be used in the invention. In the invention, non-reducing sugars described in JP-A No. 8-305039 can be preferably used.

Examples of the trehalose type oligosaccharides include saccharose and trehalose. Examples of the glucosides include alkylglucosides, phenolglucosides, and mustard seed oil glucoside. Examples of the sugar alcohols include D, L-arabite, ribitol, xylitol, D, L-sorbitos, D, L-mannitol, D, L-iditol, D, L-talitol, dulcitol, and allodulcitol. Furthermore, maltitol, obtained by hydrogenating a disaccharide, and a reductant obtained by hydrogenating an oligosaccharide (i.e., reduced starch syrup) are preferable. Of these examples, sugar alcohol and saccharose are more preferable. D-sorbitol, saccharose, and reduced starch syrup are even more preferable since they have buffer effect within an appropriate pH range and are inexpensive.

These non-reducing sugars may be used alone or in combinations of two or more. A content of the non-reducing sugar in the non-silicate developing solution is preferably 0.1 to 30 percent by mass and more preferably 1 to 20 percent by mass. When the content is less than 0.1 percent by mass, it is not easy to obtain a sufficient buffer action, and when the content exceeds 30 percent by mass, it is difficult to make a higher concentrated solution and the cost tends to rise.

The base combined with the nonreducing sugar(s) may be an alkali agent that has been known so far. Examples thereof include inorganic alkali agents such as sodium hydroxide, potassium hydroxide, lithium hydroxide, trisodium phosphate, tripotassium phosphate, triammonium phosphate, disodium phosphate, dipotassium phosphate, diammonium phosphate, sodium carbonate, potassium carbonate, ammonium carbonate, sodium hydrogencarbonate, potassium hydrogencarbonate, ammonium hydrogencarbonate, sodium borate, potassium borate and ammonium borate; and organic alkali agents such as monomethylamine, dimethylamine, trimethylamine, monoethylamine, diethyl amine, triethylamine, monoisopropylamine, diisopropylamine, triisopropylamine, n-butylamine, monoethanolamine, diethanolamine, triethanolamine, monoisopropanolamine, diisopropanolamine, ethyleneimine, ethylenediamine, and pyridine.

The bases may be used alone or in combinations of two or more. Among these bases, sodium hydroxide and potassium hydroxide are preferable. In the present invention, a developer containing an alkali-metal salt of a nonreducing sugar as the principal component may be used as the non-silicate developer, replacing the combined use of a nonreducing sugar and a base.

Alternatively, an alkaline buffer solution containing a weak acid other than the nonreducing sugar and a strong base may be used in the non-silicate developer. The weak acid preferably has a dissociation constant (pKa) of 10.0 to 13.2, and is selected from the weak acids described in “Ionization Constants of Organic Acids in Aqueous Solution” published by Pergmon Press, and others.

Specifically suitable examples thereof include alcohols such as 2,2,3,3-tetrafluoropropanol-1 and trifluoroethanol, trichloroethanol; aldehydes such as pyridine-2-aldehyde and pyridine-4-aldehyde; phenolic hydroxyl group-containing compounds such as salicylic acid, 3-hydroxy-2-naphthoic acid, catechol, gallic acid, sulfosalicylic acid, 3,4-dihydroxysulfonic acid, 3,4-dihydroxybenzoic acid, hydroquinone, pyrogallol, o-, m-, and p-cresols, and resorcinol; oximes such as acetoxime, 2-hydroxybenzaldehyde oxime, dimethyl glyoxime, ethanediamide dioxime, and acetophenone oxime; nucleic acid-derived substances such as adenosine, inosine, guanine, cytosine, hypoxanthine, and xanthine; diethylaminomethylphosphonic acid, benzimidazole, barbituric acid, and the like.

Various surfactants and organic solvents may be added as needed to the developer and replenisher, for improvement or control of developing efficiency, dispersion of development scum, or improvement of the ink compatibility of the image region of a printing plate. The surfactant is preferably an anionic, cationic, nonionic or amphoteric surfactant. In addition, a reducer such as hydroquinone, resorcin, sodium or potassium salt of an inorganic acid such as sulfurous acid or bisulfurous acid as well as an organic carboxylic acid, an antifoaming agent, a water softener, or the like may be added to the developer and replenisher as needed.

The planographic printing plate developed with the developer and replenisher is then post-treated with a rinse solution containing washing water, a surfactant, and the like and with a desensitizing solution containing gum arabic or a starch derivative. These treatments may be used in combination as the post-treatment.

Furthermore, in the case of an automatic developing machine being used to develop, it is known that, when an aqueous solution stronger in the alkalinity than that of a developing solution (replenishing solution) is added to the developing solution, without exchanging for a long time a developing solution in a developing tank, many PS plates can be processed. In the invention as well, the replenishing process can be preferably applied. A printing plate developed with the developing solution and the replenishing solution is post-treated with washing water, a rinse solution containing a surfactant and a desensitizing solution containing gum Arabic and a starch derivative. In the post-treatment of the planographic printing plate precursor that uses a photosensitive composition of the invention, these treatments can be variously combined to use.

In recent years, automatic developing machines for the printing plates have become widely used for the purpose of streamlining and standardizing the plate-making processes in the printing-plate and printing industries. These automatic developing machines generally consist of a developing unit and a post-treatment unit, a unit for conveying printing plates and various stock solution tanks, and units for spraying solutions, wherein the exposed printing plates are developed while they are conveyed horizontally and sprayed via spray nozzles with various solutions pumped out of the stock tanks. Also known is another kind of automatic developing system, wherein the printing plates are conveyed as they are immersed in treatment solution tanks filled with treating solutions one after another by means of the submerged guide rolls or the like. In this type of automatic processing, the plates are processed in the solutions, which are periodically replenished with replenisher according to the number of plates processed and the operating time. In addition, a method of essentially using only unused treating solutions, i.e., a single-round method, may also be used.

In the present invention, if the planographic printing plate obtained after the steps of image exposure, development, water washing and/or rinsing, and/or gumming has unnecessary image portions (e.g., film edge spots on the original image film and the like), elimination of the unnecessary image portions is performed. As the elimination method, although the method described for example in Japanese Patent Application Publication (JP-B) No. 2-13293 wherein an image-elimination solution is applied onto the undesirable image portions and the resulting plate is then washed with water after being left for a certain period; the method described in JP-A No. 59-174842, wherein the undesirable image portions are eliminated by irradiation of an activated light through an optical fiber and then the resulting plate is developed, may be also used.

The developed planographic printing plate thus obtained may, if desired, be coated with a desensitizing gum before it is sent to the printing process; or the plate is additionally subjected to a baking treatment a planographic printing plate higher in printing durability is desired.

If the planographic printing plate is to be subjected to a baking treatment, the plate is preferably treated before the baking treatments with an affinitizing solution described in JP-B No. 61-2518 JP-B No. 55-28062, JP-A No. 62-31859, or JP-A No. 61-159655. The methods include application of the affinitizing solution onto planographic printing plates with sponges or cotton moistened therewith, application by immersing the printing plate into a bath filled with the affinitizing solution, and application by an automatic coater. Additionally, adjustment of the coating amount for uniformity by using a squeezee or a squeezee roller after application of the affinitizing solution provides more favorable results.

The suitable coating amount of the affinitizing solution is generally 0.03 to 0.8 g/m² (as dry weight). The planographic printing plate applied with the affinitizing solution is then dried as needed and heated at high temperature in a burning processor (e.g., Burning Processor BP-1300 available from Fuji Photo Film Co.). The temperature and the period of heating vary according to the kind of the components constituting the images, but are preferably in a range of 180 to 300° C. for 1 to 20 minutes.

The planographic printing plate that has been subjected to a baking treatment may then be subjected, if needed, to treatments commonly practiced in the art such as water washing and gumming, but if a surface treatment solution containing a water-soluble polymer compound or the like is used, the so-called desensitizing treatment such as gumming or the like may be eliminated. The planographic printing plate obtained after these treatments is then mounted on an offset printing machine or the like, and it is used for printing numerous sheets of paper.

### EXAMPLES

The invention will be described with reference to examples, but a range of the invention is not limited to them.

### Examples 1 to 16, Comparative Examples 1 to 4

### [Preparation of Support]

A 0.3 mm thick JIS-A-1050 aluminum plate was processed according to steps shown below to prepare a support.

### (a) Mechanical Surface Roughening Treatment

While a suspension containing a polishing agent (silica sand) with a specific gravity of 1.12 and water was supplied as a polishing slurry to the a surface of each aluminum sheet, the and mechanical surface roughening was carried out by rotating roller type nylon brushes. The average particle size of the polishing agent was 8 μm and the maximum particle size was 50 μm. The material of the nylon brushes was 6-10 nylon and hair length and hair diameters were 45 mm and 0.3 mm, respectively. The nylon brushes were produced by implanting the hairs densely in holes formed in stainless cylinders with a diameter of φ300 mm. Three rotating brushes were used. Two supporting rollers (φ200 mm diameter) were placed in lower parts of the brushes with a separation distance of 300 mm. The brush rollers were pushed until the load of the driving motor for rotating the brushes was increased by 7 kW or more from the load before the brush rollers being pushed against the aluminum sheet. The rotation direction of the brushes was the same as the moving direction of the aluminum sheet. The rotation speed of the brushes was 200 rpm.

### (b) Alkaline Etching Treatment

Etching treatment was carried out by spraying an aqueous NaOH solution (NaOH concentration being 26% by weight and also containing an aluminum ion 6.5% by weight) to the aluminum plate at 70° C., to dissolve the aluminum sheet by an amount of 6 g/m². After that, the aluminum sheet was washed with water by spraying.

### (c) Desmutting Treatment

The aluminum plate was subjected to a desmutting treatment by spraying an aqueous solution containing 1 wt % nitric acid (additionally containing 0.5 wt % aluminum ion) at a temperature of 30° C., and then washed by spraying water. The aqueous nitric acid solutions used for desmutting was the wastewater obtained in the electrochemical surface-roughening step wherein the aluminum plates were electrochemically scratched in an aqueous nitric acid solution using an alternating electrical current.

### (d) Electrochemical Surface-Roughening Treatment

The aluminum plates were further scratched electrochemically by continuous use of a 60-Hz alternating current. The electrolyte used was an aqueous solution containing 10.5 g/L nitric acid (containing additionally 5 g/L of aluminum ion) at a temperature of 50° C. The electrochemical surface roughening was performed using a trapezoidal alternating current having a trapezoidal waveform with a transition period (TP) from zero to peak currency of 0.8 msec and a duty ratio of 1:1 with a carbon electrode as the counter electrode. Ferrite was used as the auxiliary anode. The electrolytic bath used was that of a radial cell type.

The electric current density was 30 A/dm² at peak value, and when an aluminum plate is used as the anode, the total amount of electric current applied was 220 C/dm². 5% of the current from the power source was divided and sent to the auxiliary electrode.

Subsequently, the aluminum plates were washed by a spray using well water.

### (e) Alkaline Etching Treatment

The aluminum plate was sprayed with a solution containing 26 wt % caustic soda and 6.5 wt % aluminum ion at 32° C. to melt the aluminum plate at 0.20 g/m² to remove the smut mainly containing aluminum hydroxide, which was generated during the previous electrochemical surface-roughening treatment using an alternating electrical current, and to polish the edge portion by dissolving the edge portions of the pits generated. Subsequently, the aluminum plates were washed by a spray using well water.

### (f) Desmutting Treatment

The aluminum plate was desmutted by spraying an aqueous solution containing 15 wt % nitric acid (containing additionally 4.5 wt % aluminum ion) at a temperature of 30° C., and then washed by a spray using well water. The wastewater obtained in the electrochemical surface-roughening step, wherein the aluminum plates were electrochemically scratched in an aqueous nitric acid solution using an alternating electrical current, was used as the aqueous nitric acid solution for desmutting.

### (g) Electrochemical Surface Roughening Treatment

Electrochemical surface roughening treatment was carried out continuously by using 60 Hz AC voltage. The electrolytic solution used in this step was an aqueous solution of hydrochloric acid (the concentration thereof being 7.5 g/L and also containing aluminum ion by 5 g/L) at 35° C. The AC power waveform had a trapezoidal rectangular waveform and a carbon electrode was used as an opposed electrode, to effect the electrochemical surface roughening treatment. Ferrite was used as an auxiliary anode. A radial cell type electrolytic bath was used.

The current density was 25 A/dm² at the peak value of the current and the total electricity quantity was 50 C/dm² when the aluminum sheet was used as an anode.

After that, the resulting aluminum sheet was washed with a water spray.

### (h) Alkali Etching Treatment

Etching treatment was carried out at 32° C. for the aluminum sheet by spraying a solution containing 26 wt. % sodium hydroxide and 6.5 wt. % aluminum ion thereon, to dissolve 0.10 g/m² of the aluminum sheet, so as to remove the smut, of which main component is mainly aluminum hydroxide produced during the electrochemical roughening treatment of the surface by using alternating current in the prior step. Further, the edge portions of the pits formed were dissolved to make the edge portions smooth. After that, the aluminum sheet was washed by spraying water spray.

### (i) Desmut Treatment

Desmut treatment was is carried out by spraying with an aqueous solution of 25% by weight sulfuric acid (containing aluminum ion 0.5% by weight) at 60° C. and then washing the resulting aluminum sheet was washed by spraying water spray.

### (j) Anodization Treatment

As an electrolytic solution, sulfuric acid was used. The electrolytic solution contained sulfuric acid by 170 g/L (and contained aluminum ion 0.5% by weight). The temperature of the electrolytic solution was 43° C. After then the aluminum sheet was washed with water by spraying.

The electric current density was about 30 A/dm². Final oxide film thickness was about 2.7 g/m².

### <Support A>

The respective steps of (a) to (j) were sequentially carried out with the (e) step applied so that an etching amount may be 3.4 g/m², and thereby a support A was prepared.

### <Support B>

Except that, when the support A was prepared, steps of (g), (h) and (i) were omitted, similarly to the preparation of the support A, a support B was prepared.

### <Support C>

Except that, when the support A was prepared, steps of (a), (g), (h) and (i) were omitted, similarly to the preparation of the support A, a support C was prepared.

### <Support D>

Except that, when the support A was prepared, steps of (a), (d), (e) and (f) were omitted and a sum total of electricity in the step (g) was changed so as to be 450 C/dm², similarly to the preparation of the support A, a support D was prepared.

To thus obtained supports A to D, subsequently, a silicate process shown in (k) below was applied, followed by forming an undercoat layer.

### (k) Silicate Process

An aluminum support obtained by an anodic oxidation process was dipped for 10 sec in a process tank kept at 30° C. and containing an aqueous solution of 1 mass percent of No. 1 soda silicate to apply an alkali metal silicate process (silicate process). Thereafter, water washing was applied with well water. An adhesion amount of the silicate was 5.5 mg/m².

### [Formation of Undercoat Layer]

On thus processed aluminum plate, in the beginning, by use of a wire bar, an undercoating solution (1) below was coated and dried at 80° C. for 20 sec. A coated amount after drying was 0.02 g/m².

Composition of undercoat layer

| | |
|---|---|
| Compound below (A number next to a parenthesis shows a | 0.1 g |
| molar ratio.) | |
| Methanol | 100.0 g |

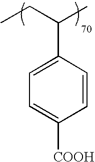

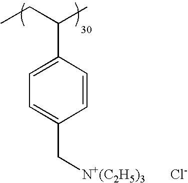

As shown in Table 1, on the obtained supports A to D, any one of photosensitive layers 1 to 4 described below was formed to prepare infrared laser-sensitive planographic printing plate precursors.

### [Photosensitive Layer 1]

On a support on which an undercoat layer was disposed, a coating solution A having a composition below was coated by use of a wire bar, followed by drying for 40 sec in a dry oven kept at 150° C. so that a coated amount may be 0.8 g/m², thereby an underlayer was disposed.

<Coating solution A>

| | |
|---|---|
| Copolymer of N-(p-aminosulfonylphenyl)methacrylamide/ | 3.5 g |
| methyl methacrylate/acrylonitrile = 35/35/30 (molar ratio) | |
| (weight average molecular weight: 65,000) | |
| m, p-cresol novolac (m/p ratio = 6/4, weight average molecular | 0.6 g |
| weight: 6000) | |
| Infrared absorbent shown below (cyanine dye A) | 0.25 g |
| Dye obtained by changing a counter anion of ethyl violet to | 0.15 g |
| 6-hydroxy-β-naphthalene sulfonate) | |
| Bisphenol sulfone | 0.3 g |
| Tetrahydrophthalic acid | 0.4 g |
| Fluorinated surfactant (Megafac F-780, produced by Dainippon | 0.02 g |
| Ink & Chemicals Inc.) | |
| Methyl ethyl ketone | 60 g |
| Propylene glycol monomethyl ether | 20 g |
| γ-butylolactone | 20 g |

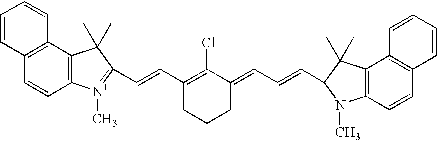

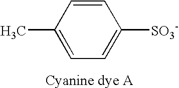

After the underlayer was disposed, a coating solution B having a composition below was coated by use of a wire bar to form an upper layer, followed by drying for 40 sec at 150° C., and thereby an infrared laser-sensitive planographic printing plate precursor where a total coated amount of the lower layer and upper layer was 1.0 g/m² was obtained.

<Coating Solution B>

| | |
|---|---|
| Novolac resin (m-cresol/p-cresol/phenol = 3/2/5, weight average | 1.7 g |
| molecular weight: 8,000) | |
| Infrared absorbent mentioned above (cyanine dye A) | 0.15 g |
| Compound Q shown below | 0.35 g |
| Fluorinated surfactant (Megafac F-780, produced by Dainippon | 0.03 g |
| Ink & Chemicals Inc.) | |
| Copolymer of tridecafluorooctyl methacrylate/2-adamantyl | 0.1 g |
| acrylate/2-carboxyethyl methacrylate = 30/50/20 | |
| having a weight average molecular weight of 30,000 | |
| Acrylic resin (copolymer involving the invention or reference | 0.3 g |
| acrylic resin, acrylic resin described in Table 1) | |
| Methyl ethyl ketone | 33 g |
| 1-methoxy-2-propanol | 67 g |

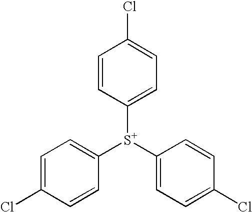

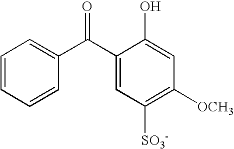

Compound Q

### [Photosensitive Layer 2]

On a support on which an undercoat layer was disposed, a coating solution C having a composition below was coated by use of a wire bar and, thereafter, dried at 150° C. for 40 sec in a dry oven so that a coated amount may be 1.3 g/m², and thereby an underlayer was disposed.

<Coating Solution C>

| | |
|---|---|
| Copolymer of N-phenylmaleimide/methacrylamide/ | 0.85 g |
| methacrylic acid = 45/35/20 (molar ratio)(weight average | |
| molecular weight: 50,000) | |
| Ethyl violet | 0.05 g |
| Fluorinated surfactant (Megafac F-780, produced by | 0.02 g |
| Dainippon Ink & Chemicals Inc.) | |
| Methyl ethyl ketone | 5 g |
| Propylene glycol monomethyl ether | 15 g |
| γ-butylolactone | 5 g |

After the underlayer was disposed, a coating solution B having above-mentioned composition was coated by use of a wire bar, followed by drying for 40 sec at 150° C. so that a total coated amount may be 1.8 g/m², and thereby an infrared laser-sensitive planographic printing plate precursor was obtained.

### [Photosensitive Layer 3]

On a support on which an undercoat layer was disposed, a coating solution D having a composition below was coated by use of a wire bar, followed by drying in a drying oven for 40 sec at 160° C. so that a coated amount may be 1.20 g/m², and thereby an infrared laser-sensitive planographic printing plate precursor was obtained.

<Coating Solution D>

| | |
|---|---|
| Copolymer of 2-(N′-(4-carboxyphenyl)ureido)ethyl | 0.40 g |
| methacrylate/N-phenylmaleimide = 75/25 | |
| (weight ratio) (weight average molecular weight: 30,000) | |
| Copolymer of N-phenylmaleimide/methacrylamide/ | 0.45 g |
| methacrylic acid = 45/35/20 (molar ratio) | |
| (weight average molecular weight: 50,000) | |
| Infrared absorbent mentioned above (cyanine dye A) | 0.10 g |
| Ethyl violet | 0.05 g |
| Fluorinated surfactant (Megafac F-780, produced | 0.02 g |
| by Dainippon Ink & Chemicals Inc.) | |
| Acrylic resin (copolymer involving the invention, | 0.1 g |
| acrylic resin described in Table 1) | |
| Methyl ethyl ketone | 5 g |
| Propylene glycol monomethyl ether | 20 g |
| γ-butylolactone | 5 g |

### [Photosensitive Layer]

On a support on which an undercoat layer was disposed, a coating solution E having a composition below was coated by use of a wire bar, followed by drying in a drying oven for 60 sec at 160° C. so that a coated amount may be 1.60 g/m², and thereby an infrared laser-sensitive planographic printing plate precursor was obtained.

<Coating Solution E>

| | |
|---|---|
| Novolac resin (2,3-xylenol/m-cresol/p-cresol = 1/5/4, | 1.0 g |
| weight average molecular weight: 8,000) | |
| Infrared absorbent mentioned above (cyanine dye A) | 0.10 g |
| Ethyl violet | 0.05 g |
| Fluorinated surfactant (Megafac F-780, produced by | 0.02 g |
| Dainippon Ink & Chemicals Inc.) | |
| Acrylic resin (copolymer involving the invention, | 0.1 g |
| acrylic resin described in Table 1) | |
| Methyl ethyl ketone | 20 g |

Supports and photosensitive layers obtained according to above-mentioned preparation methods and acrylic resins (copolymers involving the invention), respectively, were combined as shown in Table 1, thereby, infrared laser-sensitive planographic printing plate precursors of examples 1 through 16 and comparative examples 1 through 4 were obtained.

### [Evaluation of Infrared Laser-Sensitive Planographic Printing Plate Precursor]

### [Evaluation of Developability]

The obtained infrared laser-sensitive planographic printing plate precursor was mounted on a Trendsetter (trade name, produced by Creo Products Inc.) and, under exposure energy of 150 mJ/cm², a test pattern was image-wise drawn. Thereafter, by use of a PS Processor LP-940H (trade name, produced by Fuji Photo Film Co., Ltd.), with a liquid temperature maintained at 30° C., the planographic printing plate precursor was developed for 12 sec to obtain an evaluation sample. As a developing solution at this time, a liquid obtained by mixing a developing solution DT-2R (trade name, produced by Fuji Photo Film Co., Ltd.) and tap water at a ratio of 1:6.5, followed by blowing carbon dioxide therein was used. Furthermore, as a finisher, a finisher FG-1 (trade name, produced by Fuji Photo Film Co., Ltd.) diluted with tap water at a ratio of 1:1 was used.

The conductivity of the developing solution was varied at an interval of 2 mS/cm from 58 mS/cm to 42 mS/cm, a non-image portion of the obtained sample was observed with a loupe and the conductivity where a spot-like residual film started appearing was shown by a numerical value. Results thereof are shown in Table 1. The smaller the numerical value is, the better the non-image portion is. This means that even a developing solution low in a liquid temperature allows developing.

### [Evaluation of Sludge Precipitation]

Then, 1 m² of the obtained infrared laser-sensitive planographic printing plate precursor was mounted on a Trendsetter (trade name, produced by Creo Products Inc.) and an entire surface was exposed at exposure energy of 150 mJ/cm². Thereafter, a developing solution DT-2 (trade name, produced by Fuji Photo Film Co., Ltd.) and tap water were mixed at a ratio of 1:8, and 50 ml thereof was used to develop. After a processed liquid was left for 24 hr in a hermetically sealed glass bottle, whether there is precipitate on a bottle bottom or not was confirmed, and when no precipitate was found it was evaluated good, and, when precipitate was found, it was evaluated poor. Results thereof are shown in Table 1.

### [Evaluation of Inking Property]

The obtained infrared laser-sensitive planographic printing plate precursor was mounted on a Trendsetter (trade name, produced by Creo Products Inc.) and, under exposure energy of 150 mJ/cm², a test pattern was image-wise drawn. Thereafter, by use of a PS Processor LP-940H (trade name, produced by Fuji Photo Film Co., Ltd.), with a liquid temperature maintained at 30° C., the planographic printing plate precursor was developed for 12 sec to obtain an evaluation sample. As a developing solution at this time, a liquid obtained by mixing a developing solution DT-2R (trade name, produced by Fuji Photo Film Co., Ltd.) and tap water at a ratio of 1:8 was used. Furthermore, as a finisher, a finisher FG-1 (trade name, produced by Fuji Photo Film Co., Ltd.) diluted with tap water at a ratio of 1:1 was used.

An obtained printing plate was mounted on a printing press LITHRONE 25 (trade name, produced by Komori Corp.), and then printing was started with Best One SUPER Light Resistant Rouge Ink (trade name, produced by T & K TOKA CO., LTD.,) and a liquid obtained by diluting CDS903 (trade name, produced by Tokyo Ink Co., Ltd.) to 1% as damping water. After the printing was started and it was confirmed that excellent printed matters could be obtained at damping water scale of 5, the scale of damping water was varied to 7 and 100-th printed matter was visually observed. When an excellent printed matter same as that at the damping water scale of 5 was obtained, it was evaluated as good, and, when density decrease was observed, it was evaluated as poor. Results thereof are shown in Table 1.

TABLE 1

| | | | Acrylic Resin | | Evaluation Result | | |
|---|---|---|---|---|---|---|---|
| | | Kind of | | Weight Average | | Sludge | Inking |
| | Kind of Support | Photosensitive Layer | Composition | Molecular Weight | Developability | Precipitation | Property |
| Example 1 | Support A | Photosensitive Layer 1 | Composition | 80,000 | 44 | Good | Good |
| | | | Example (A) | | | | |
| Example 2 | Support A | Photosensitive Layer 1 | Composition | 150,000 | 44 | Good | Good |
| | | | Example (C) | | | | |
| Example 3 | Support A | Photosensitive Layer 1 | Composition | 40,000 | 44 | Good | Good |
| | | | Example (D) | | | | |
| Example 4 | Support A | Photosensitive Layer 1 | Composition | 70,000 | 44 | Good | Good |
| | | | Example (E) | | | | |
| Example 5 | Support A | Photosensitive Layer 1 | Composition | 50,000 | 44 | Good | Good |
| | | | Example (I) | | | | |
| Example 6 | Support A | Photosensitive Layer 1 | Composition | 10,000 | 44 | Good | Good |
| | | | Example (L) | | | | |
| Example 7 | Support A | Photosensitive Layer 1 | Composition | 40,000 | 44 | Good | Good |
| | | | Example (Q) | | | | |
| Example 8 | Support A | Photosensitive Layer 2 | Composition | 100,000 | 44 | Good | Good |
| | | | Example (B) | | | | |
| Example 9 | Support A | Photosensitive Layer 3 | Composition | 80,000 | 46 | Good | Good |
| | | | Example (F) | | | | |
| Example 10 | Support A | Photosensitive Layer 4 | Composition | 40,000 | 44 | Good | Good |
| | | | Example (P) | | | | |
| Example 11 | Support B | Photosensitive Layer 1 | Composition | 30,000 | 46 | Good | Good |
| | | | Example (D) | | | | |
| Example 12 | Support B | Photosensitive Layer 4 | Composition | 50,000 | 44 | Good | Good |
| | | | Example (K) | | | | |
| Example 13 | Support C | Photosensitive Layer 1 | Composition | 20,000 | 46 | Good | Good |
| | | | Example (G) | | | | |
| Example 14 | Support C | Photosensitive Layer 4 | Composition | 100,000 | 44 | Good | Good |
| | | | Example (Q) | | | | |
| Example 15 | Support D | Photosensitive Layer 1 | Composition | 60,000 | 44 | Good | Good |
| | | | Example (E) | | | | |
| Example 16 | Support D | Photosensitive Layer 4 | Composition | 50,000 | 44 | Good | Good |
| | | | Example (N) | | | | |
| Comparative | Support A | Photosensitive Layer 1 | No addition | — | 44 | Good | Poor |
| Example 1 | | | | | | | |
| Comparative | Support A | Photosensitive Layer 1 | Composition | 50,000 | 50 | Good | Good |
| Example 2 | | | (X) | | | | |
| Comparative | Support A | Photosensitive Layer 1 | Composition | 20,000 | 50 | Poor | Good |
| Example 3 | | | (Y) | | | | |
| Comparative | Support A | Photosensitive Layer 4 | No addition | — | 44 | Good | Poor |
| Example 4 | | | | | | | |

In Table 1, composition examples (A) to (N) show compositions cited as one example of compositions of copolymers involving the invention. Furthermore, a composition (X) shows i-butyl methacrylate/methyl methacrylate/methacrylic acid (molar ratio: 40/30/30) and a composition (Y) shows a formaldehyde condensation resin of p-t-butyl phenol.

From Table 1, all infrared laser-sensitive planographic printing plate precursors of examples were excellent in the developability and inking property and did not show sludge precipitation after development. On the other hand, photosensitive planographic printing plates of comparative examples 1 and 4, in which a resin was not added, were poor in the inking property. Furthermore, photosensitive planographic printing plates of comparative examples 2 and 3, in which a resin other than the copolymer involving the invention was added, were poor in the developability, and a planographic printing plate of comparative example 3 generated sludge.

According to the invention, an infrared laser-sensitive planographic printing plate precursor that is excellent not only in the inking property of an image portion to enable to obtain excellent printed matters but also excellent as well in the developability and, even when many plates are continuously processed, can inhibit residue or sludge from generating in a developing solution can be provided.

<1> An infrared laser-sensitive planographic printing plate precursor, comprising: a support having a hydrophilic surface; and a single or a plurality of photosensitive layers disposed on the support having a hydrophilic surface, wherein the outermost layer of the photosensitive layer(s) comprises an infrared absorbent and a copolymer that includes, as copolymerization components, (i) an acrylate or methacrylate having an alkyl group having four or more carbon atoms, (ii) an acrylate or methacrylate having an alkyl group having 1 to 3 carbon atoms, and (iii) a polymerizing monomer having an acid group, and the amount of the acrylate or methacrylate having an alkyl group having four or more carbon atoms is in a range of 0.1 to 20 mole percent of the copolymer.

<2> The infrared laser-sensitive planographic printing plate precursor of item <1>, wherein the amount of the acrylate or methacrylate having an alkyl group having four or more carbon atoms is in a range of 1 to 20 mole percent of the copolymer.

<3> The infrared laser-sensitive planographic printing plate precursor of item <1>, wherein the amount of the acrylate or methacrylate having an alkyl group having four or more carbon atoms is in a range of 5 to 18 mole percent of the copolymer.

<4> The infrared laser-sensitive planographic printing plate precursor of any one of items <1>o <3>, wherein the weight average molecular weight of the copolymer is in a range of 5,000 to 300,000.

<5> The infrared laser-sensitive planographic printing plate precursor of any one of items <1> to <5>, wherein the content of the copolymer is in a range of 1 to 25% by mass of the copolymer.

<6> The infrared laser-sensitive planographic printing plate precursor of any one of items <1> to <5>, further comprising an alkali-soluble polymer compound or swelling polymer compound.

<7> The infrared laser-sensitive planographic printing plate precursor of item <6>, wherein the polymer compound is a novolac resin and/or a xylenol resin.

<8> The infrared laser-sensitive planographic printing plate precursor of item <7>, wherein the weight average molecular weight of the novolac resin is in a range of 500 to 20,000.

<9> The infrared laser-sensitive planographic printing plate precursor of item <7>, wherein the weight average molecular weight of the xylenol resin is 2,000 or more.

<10> The infrared laser-sensitive planographic printing plate precursor of any one of items <1> to <9>, wherein a layer below the uppermost layer of the photosensitive layer includes an infrared absorbent.

<11> An infrared laser-sensitive planographic printing plate precursor, comprising:

a support having a hydrophilic surface; and a single or a plurality of photosensitive layers disposed on the support having a hydrophilic surface, wherein the outermost layer of the photosensitive layer includes an infrared absorbent and, as copolymerization components, (i) an acrylate or methacrylate having an alkyl group having four or more carbon atoms, (ii) an acrylate or methacrylate having an alkyl group having 1 to 3 carbon atoms, and (iii) a polymerizing monomer having an acid group, and an amount a of the acrylate or methacrylate having an alkyl group having four or more carbon atoms of the outermost photosensitive layer, an amount b of the acrylate or methacrylate having an alkyl group having 1 to 3 carbon atoms of the outermost photosensitive layer, and an amount c of the polymerizing monomer having an acid group of the outermost photosensitive layer are in the following ranges: 0.1 mole percent≦a≦20 mole percent; 25 mole percent≦b≦90 mole percent; 5 mole percent≦c≦60 mole percent; and a+b+c≦100 mole percent.

<12> The infrared laser-sensitive planographic printing plate precursor of item <11>, wherein the layer directly below the outermost layer of the photosensitive layer includes an infrared absorbent.

All publications, patent applications, and technical standards mentioned in this specification are herein incorporated by reference to the same extent as if such individual publication, patent application, or technical standard was specifically and individually indicated to be incorporated by reference.

It will be obvious to those having skill in the art that many changes may be made in the above-described details of the preferred embodiments of the present invention. The scope of the invention, therefore, should be determined by the following claims.

What is claimed is:

1. An infrared laser-sensitive planographic printing plate precursor, comprising:
a support having a hydrophilic surface; and
a single layer or a plurality of photosensitive layers disposed on the support having a hydrophilic surface, wherein
the outermost layer of the photosensitive layer(s) comprises an infrared absorbent and a copolymer that includes, as copolymerization components, (i) an acrylate or methacrylate having an alkyl group having four or more carbon atoms, (ii) an acrylate or methacrylate having an alkyl group having 1 to 3 carbon atoms, and (iii) a polymerizing monomer having an acid group, and the amount of the acrylate or methacrylate having an alkyl group having four or more carbon atoms is in a range of 0.1 to 20 mole percent of the copolymer.

2. The infrared laser-sensitive planographic printing plate precursor of claim 1, wherein the amount of the acrylate or methacrylate having an alkyl group having four or more carbon atoms is in a range of 1 to 20 mole percent of the copolymer.

3. The infrared laser-sensitive planographic printing plate precursor of claim 1, wherein the amount of the acrylate or methacrylate having an alkyl group having four or more carbon atoms is in a range of 5 to 18 mole percent of the copolymer.

4. The infrared laser-sensitive planographic printing plate precursor of claim 1, wherein the weight average molecular weight of the copolymer is in a range of 5,000 to 300,000.

5. The infrared laser-sensitive planographic printing plate precursor of claim 1, wherein the content of the copolymer is in a range of 1 to 25% by mass of the outermost photosensitive layer.

6. The infrared laser-sensitive planographic printing plate precursor of claim 1, further comprising:
an alkali-soluble polymer compound or a swelling polymer compound.

7. The infrared laser-sensitive planographic printing plate precursor of claim 6, wherein the polymer compound is a novolac resin and/or a xylenol resin.

8. The infrared laser-sensitive planographic printing plate precursor of claim 7, wherein the weight average molecular weight of the novolac resin is in a range of 500 to 20,000.

9. The infrared laser-sensitive planographic printing plate precursor of claim 7, wherein the weight average molecular weight of the xylenol resin is 2,000 or more.

10. The infrared laser-sensitive planographic printing plate precursor of claim 1, wherein a layer below the uppermost layer of the photosensitive layer includes an infrared absorbent.

11. An infrared laser-sensitive planographic printing plate precursor, comprising:
a support having a hydrophilic surface; and
a single layer or a plurality of photosensitive layers disposed on the support having a hydrophilic surface, wherein
the outermost layer of the photosensitive layer includes an infrared absorbent and, as copolymerization components, (i) an acrylate or methacrylate having an alkyl group having four or more carbon atoms, (ii) an acrylate or methacrylate having an alkyl group having 1 to 3 carbon atoms, and (iii) a polymerizing monomer having an acid group, and an amount a of the acrylate or methacrylate having an alkyl group having four or more carbon atoms of the outermost photosensitive layer, an amount b of the acrylate or methacrylate having an alkyl group having 1 to 3 carbon atoms of the outermost photosensitive layer, and an amount c of the polymerizing monomer having an acid group of the outermost photosensitive layer are in the following ranges:
0.1 mole percent≦a≦20 mole percent;
25 mole percent≦b≦90 mole percent;,
5 mole percent≦c≦60 mole percent; and
a+b+c≦100 mole percent.

12. The infrared laser-sensitive planographic printing plate precursor of claim 11, wherein the layer directly below the outermost layer of the photosensitive layer includes an infrared absorbent.
